(19) United States
(12) Patent Application Publication
(10) Pub. No.: US 2026/0006872 A1
(43) Pub. Date: Jan. 1, 2026

(54) SEMICONDUCTOR DEVICES USING OXYGEN-BASED TREATMENT DURING ETCHING

(71) Applicant: Taiwan Semiconductor Manufacturing Co., Ltd., Hsinchu (TW)

(72) Inventors: Jyun-De Wu, New Taipei City (TW); Ching-Yang Chu, Hsinchu (TW); Yuan-Tien Tu, Puzih (TW)

(21) Appl. No.: 18/754,907

(22) Filed: Jun. 26, 2024

(51) Int. Cl. H01L 29/06; H01L 21/02; H01L 21/768; H01L 29/417; H01L 29/423; H01L 29/66; H01L 29/775

(52) U.S. Cl. CPC H10D 62/121; H01L 21/02362; H01L 21/76829; H10D 30/6729; H10D 64/021; H10D 30/014; H10D 30/43; H10D 30/6735

(57) ABSTRACT

An embodiment is a method including forming a first interlayer dielectric (ILD) over a transistor structure, forming first conductive contacts through the first ILD to the transistor structure, and forming a first contact etch stop layer (CESL) over the first conductive contacts and the first ILD. The method may include forming a second ILD over the first CESL. Moreover, the method may include forming a second conductive contact through the second ILD, the first CESL, and first ILD to the transistor structure. The method may also include etching a recess into the second ILD and the first CESL. Furthermore, the method may include performing a treatment in the recess to form a treated layer in the first CESL. Additionally, the method may include forming a first conductive feature in the recess, the first conductive feature being electrically coupled to the first conductive contacts.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 10C, 11A, 11B, 11C, 12A, 12B, 12C, 12D, 13A, 13B, 13C, 14A, 14B, 15A, 15B, 15C, 16A, 16B, 17A, 17B, 17C, 18A, 18B, 18C, 19A, 19B, 19C, 20A, 20B, and 20C are cross-sectional views of intermediate stages in the manufacturing of nano-FETs, in accordance with some embodiments.

FIGS. 21A, 21B, and 21C are cross-sectional views of a nano-FET, in accordance with some embodiments.

FIGS. 22, 23, 24, 25, 26, 27, 28A, 28B, and 28C illustrate cross-sectional views of further processing of the nano-FETS, in accordance with some embodiments.

FIGS. 29A and 29B illustrate cross-sectional views of further processing of the nano-FETS, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to methods and structures for semiconductor devices, particularly focusing on the challenges associated with the formation of conductive features in semiconductor devices as feature sizes continue to decrease. As the semiconductor industry strives to enhance the integration density of electronic components, the reduction in minimum feature sizes introduces new challenges, including the potential for increased leakage currents between closely spaced features. This leakage can degrade device performance and reliability, necessitating innovative solutions to mitigate such issues.

In some aspects, the disclosed methods involve the formation of a first interlayer dielectric (ILD) over a transistor structure, followed by the formation of conductive contacts through the ILD to the transistor structure. A contact etch stop layer (CESL) is then formed over the conductive contacts and the ILD. Subsequent layers and features are built upon this structure, including a second ILD and additional conductive contacts. In some embodiments, the disclosed methods includes etching a recess into the second ILD and the CESL, followed by an oxygen-based treatment within the recess. This treatment modifies the CESL and any contact spacers present, forming a treated layer that serves as a protective barrier against leakage.

The oxygen-based treatment is an innovative aspect of the disclosed methods, as it includes exposing the recess to an oxygen-containing gas at specific pressures, potentially in combination with inert gases such as nitrogen, argon, or noble gases. The resulting treated layer formed in the CESL and contact spacers has controlled dimensions, with thickness and width ranges that are tailored to provide effective leakage protection while maintaining the structural integrity of the semiconductor device.

The disclosed methods and structures offer several advantages, including improved electrical isolation between conductive features, enhanced device performance, and increased reliability. By addressing the leakage current challenges associated with advanced semiconductor devices, the disclosed methods and structures contribute to the ongoing evolution of the semiconductor industry, enabling the production of more complex and capable electronic components for a wide range of applications.

Embodiments are described below in a particular context, a device comprising nano-FETs. Various embodiments may be applied, however, to dies comprising other types of transistors (e.g., fin field effect transistors (FinFETs), planar transistors, or the like) in lieu of or in combination with the nano-FETs.

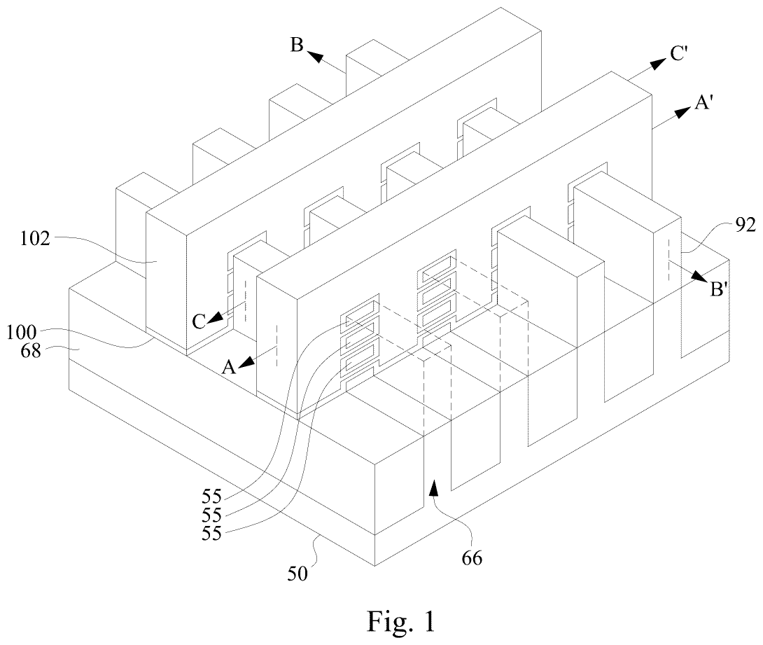

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

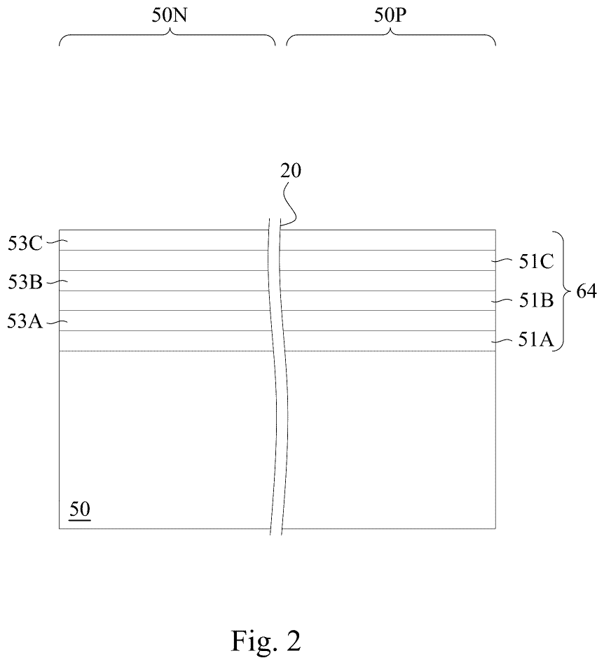

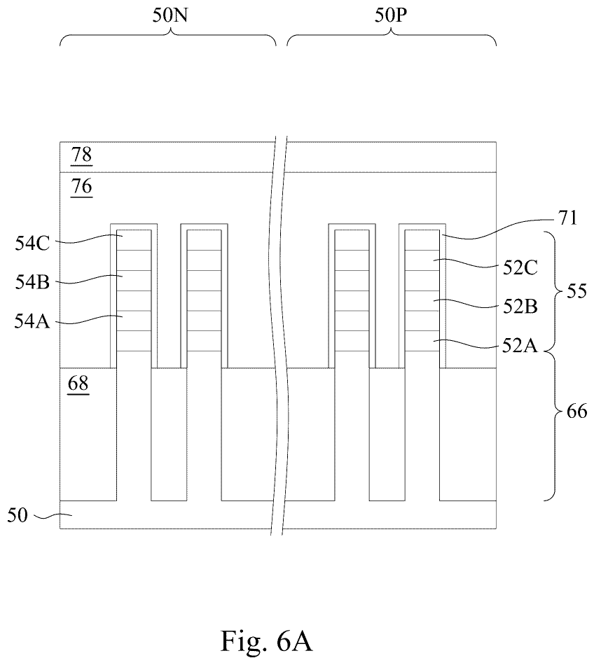

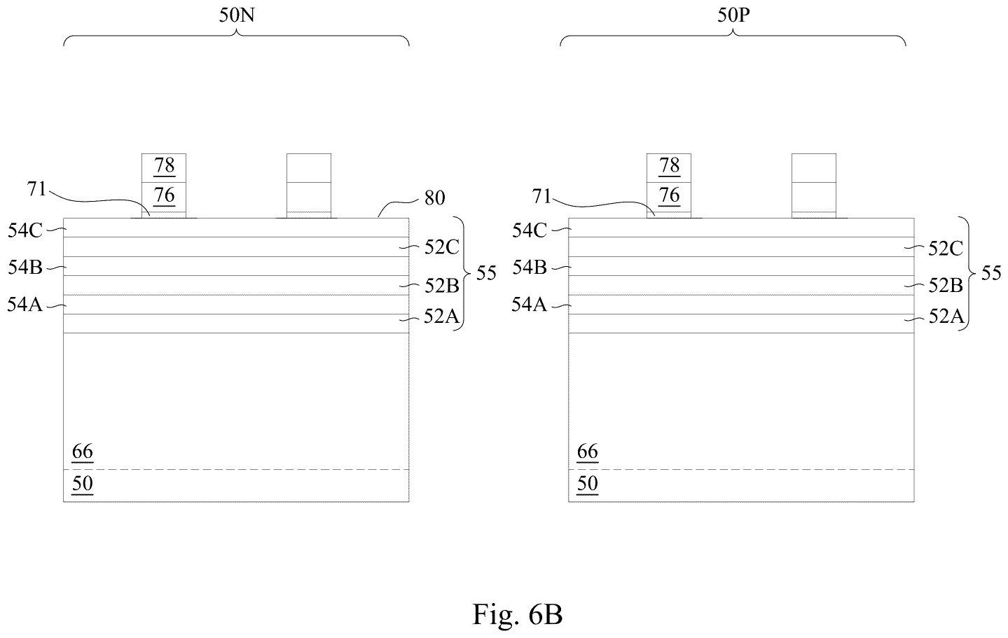

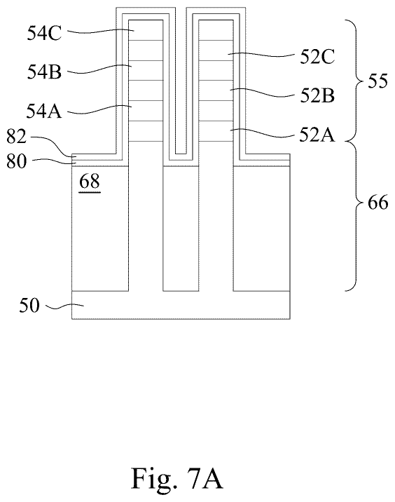

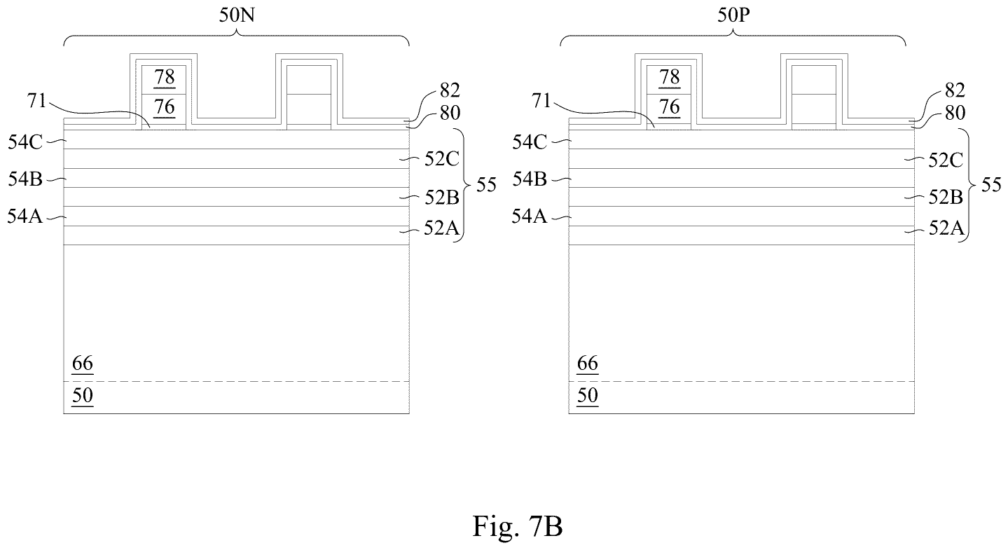

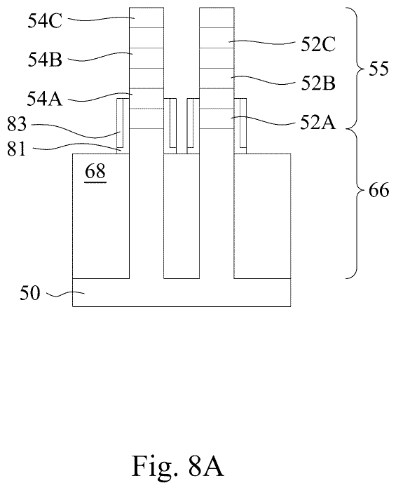

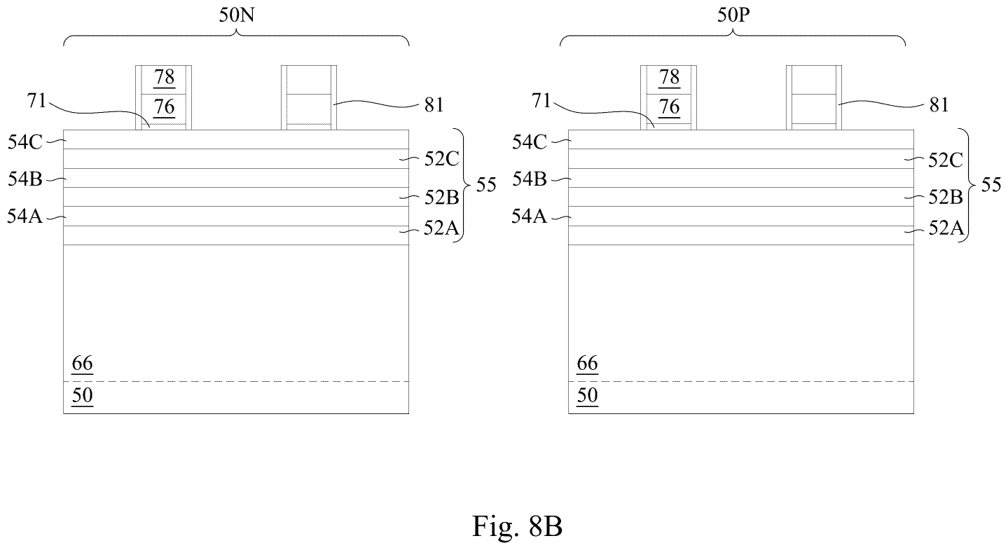

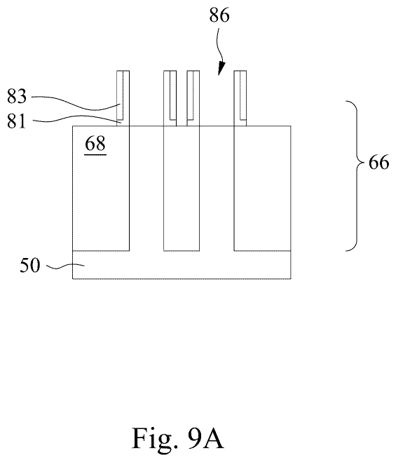

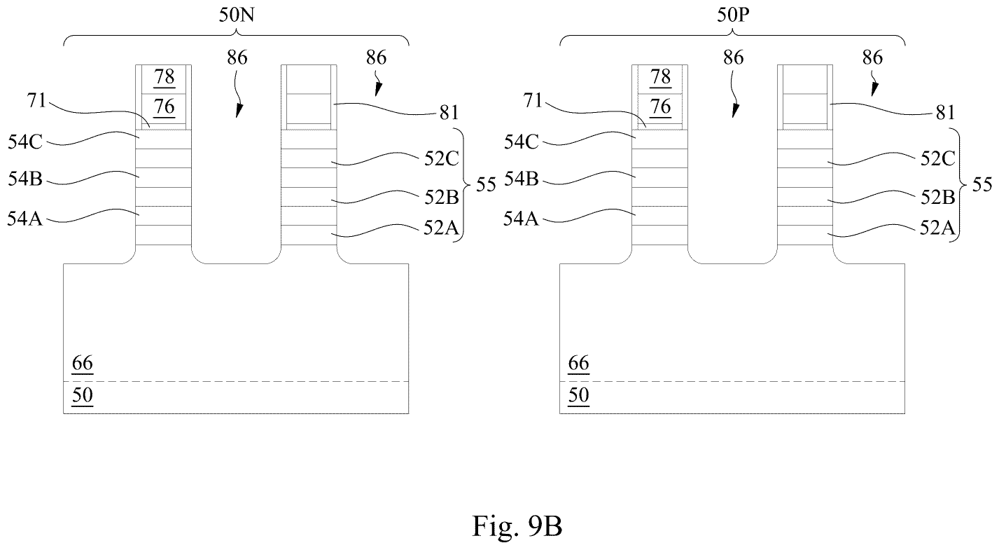

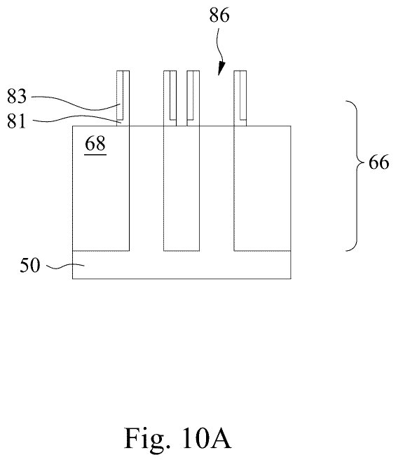

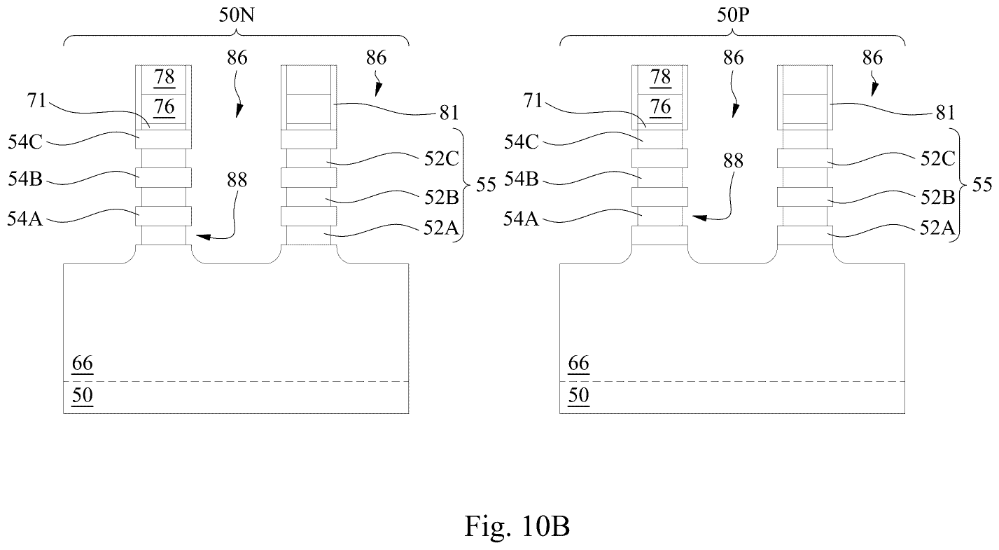

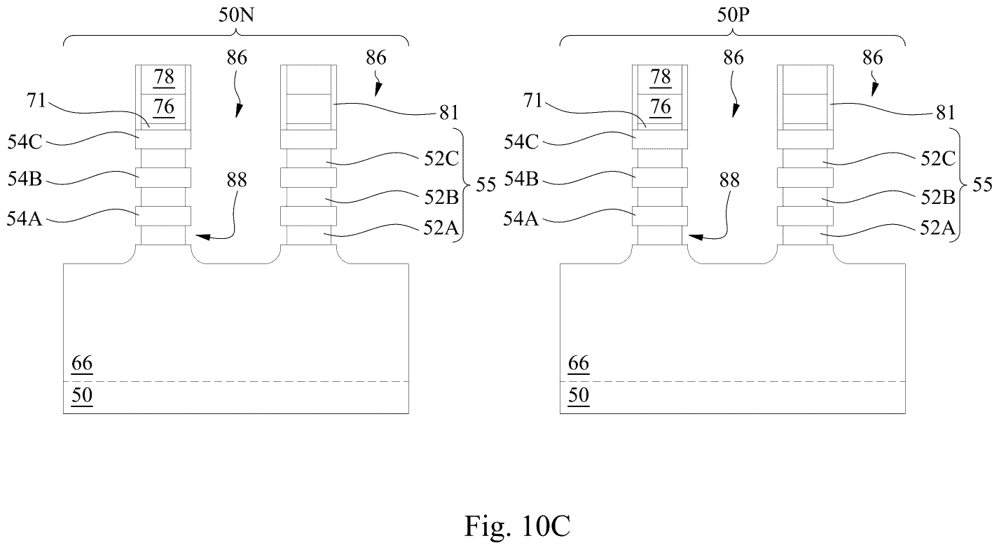

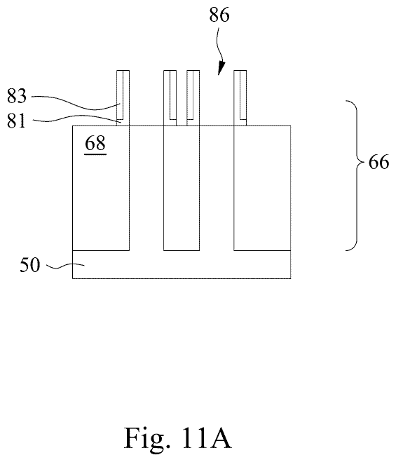

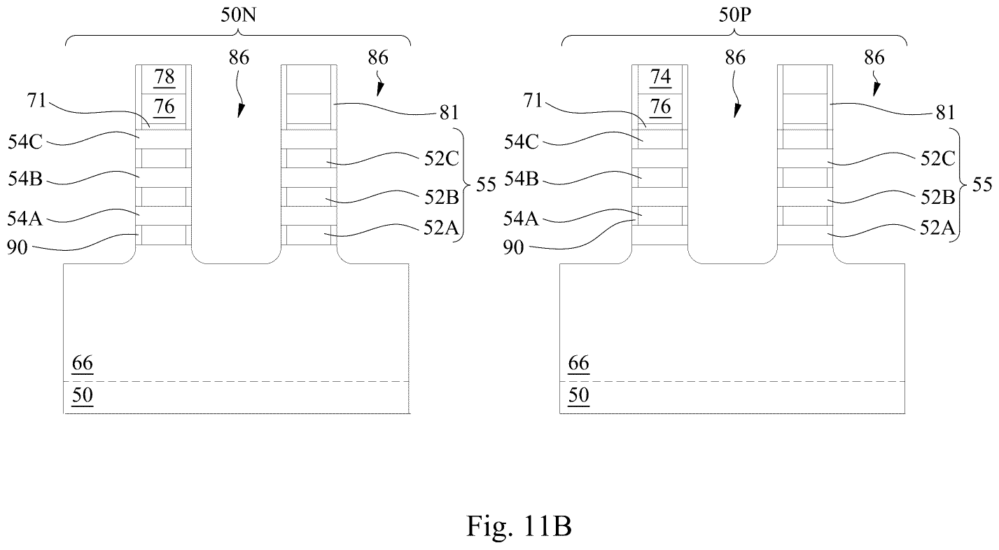

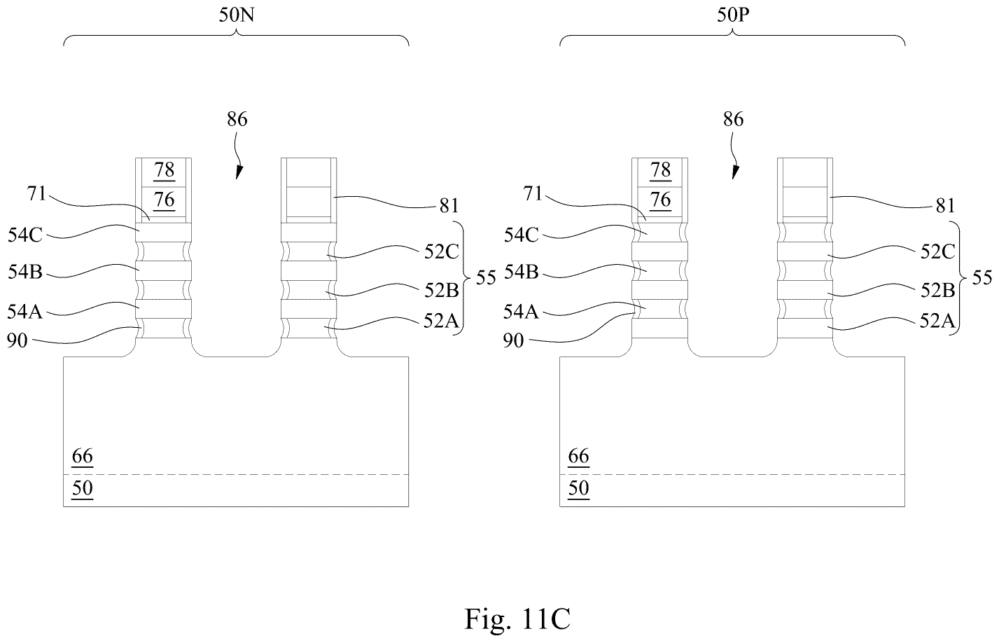

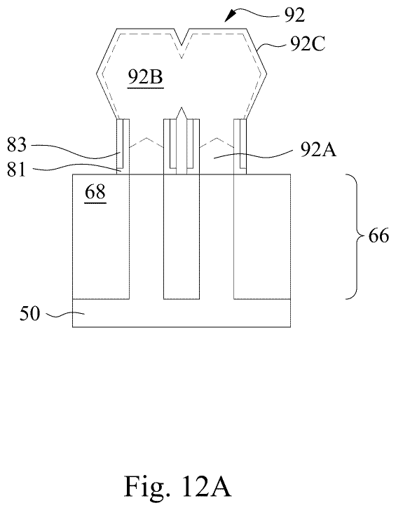

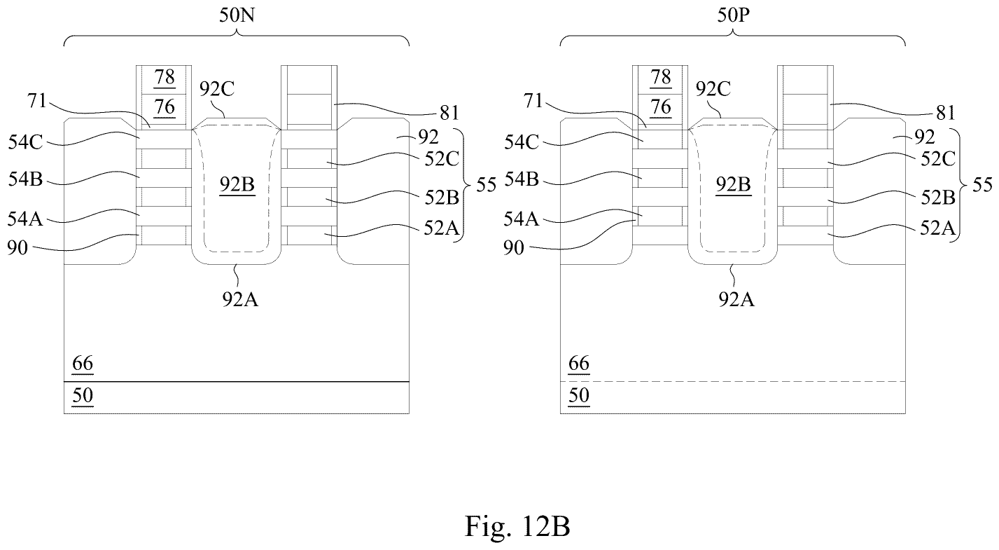

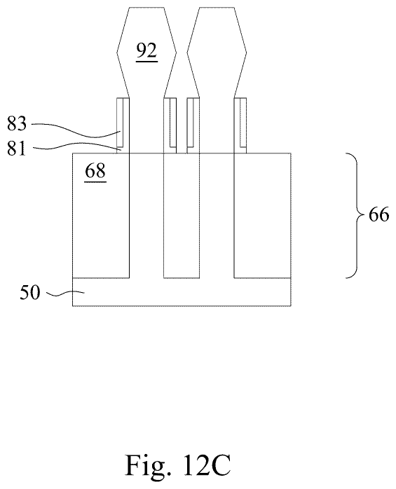

FIGS. 2 through 20C are cross-sectional views of intermediate stages in the manufacturing of nano-FETs, in accordance with some embodiments. FIGS. 2 through 5, 6A, 13A, 14A, 15A, 16A, 17A, 18A, 19A, 20A, and 21A illustrate reference cross-section A-A′ illustrated in FIG. 1. FIGS. 6B, 7B, 8B, 9B, 10B, 10C, 11B, 11C, 12B, 12D, 13B, 14B, 15B, 16B, 17B, 18B, 19B, 20B, and 21B illustrate reference cross-section B-B′ illustrated in FIG. 1. FIGS. 7A, 8A, 9A, 10A, 11A, 12A, 12C, 13C, 18C, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

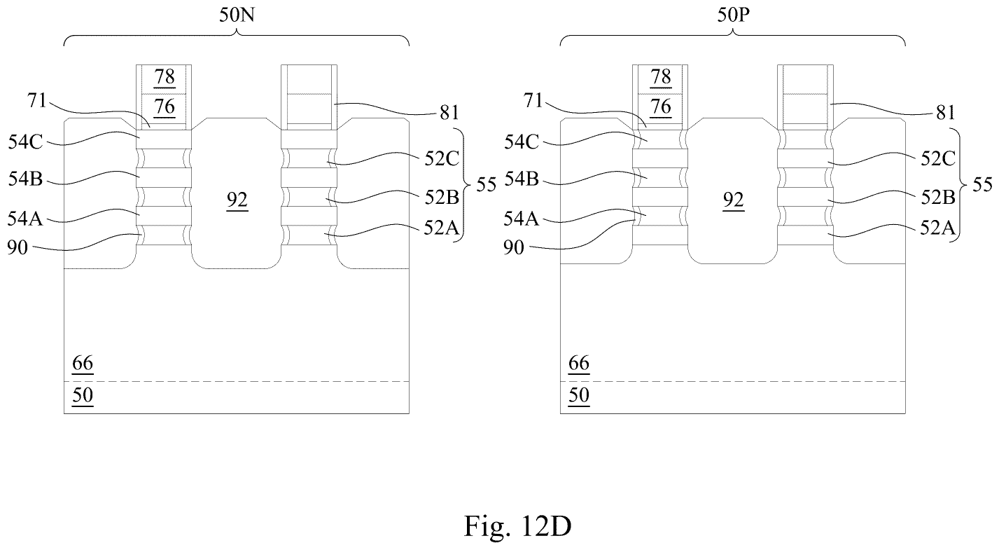

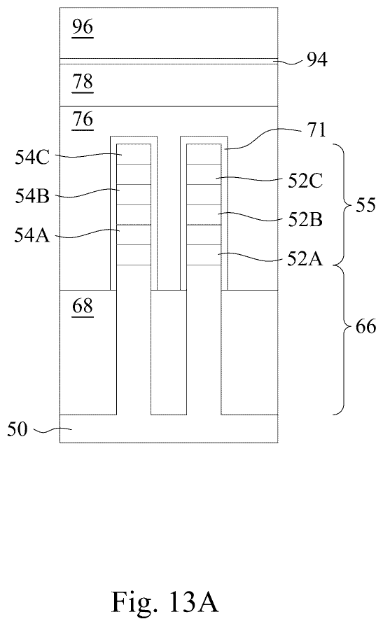

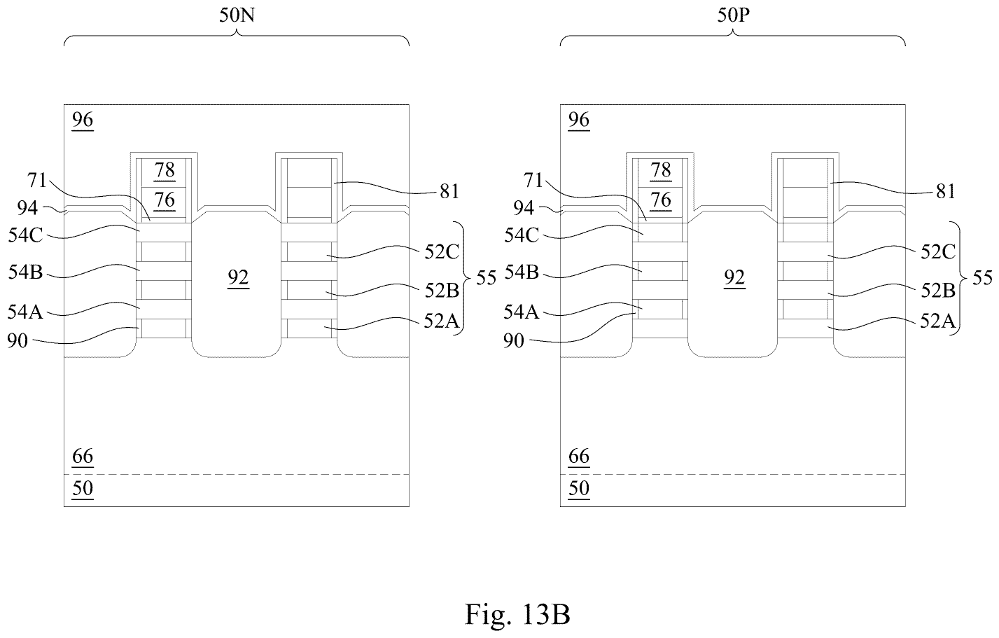

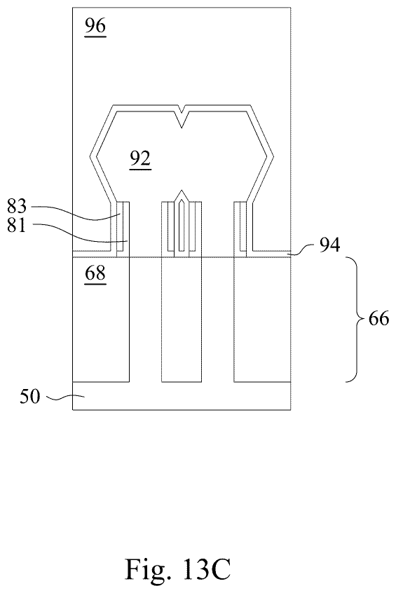

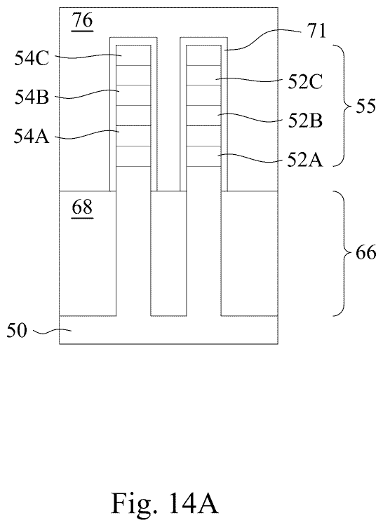

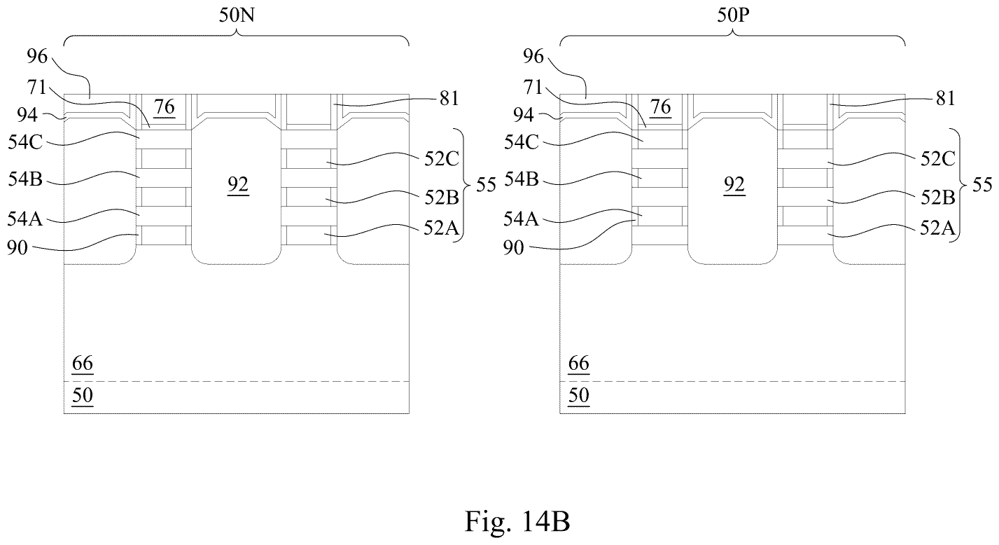

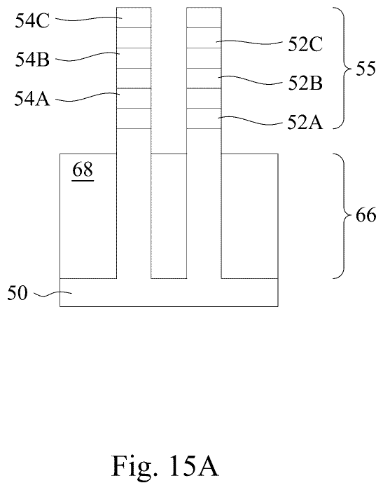

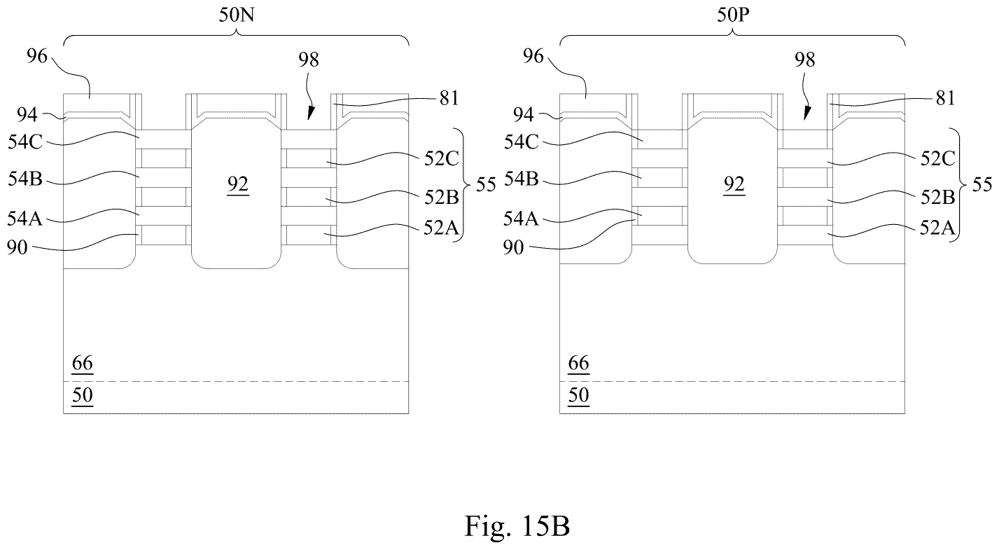

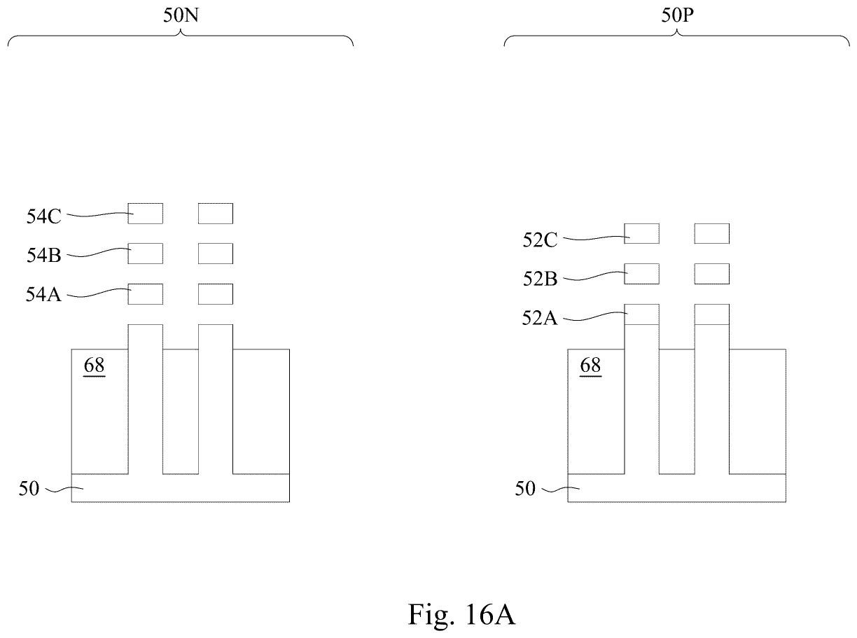

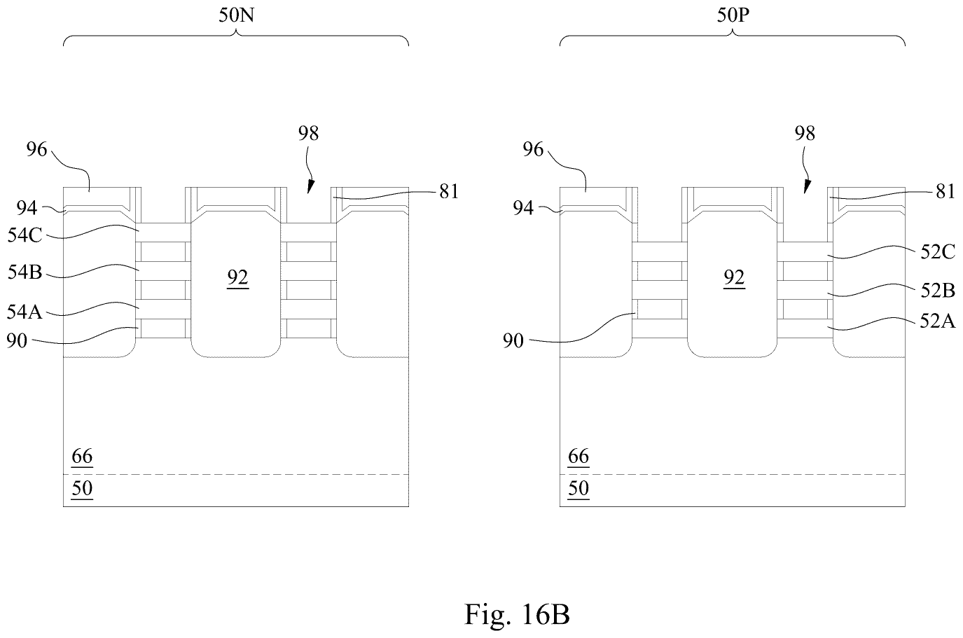

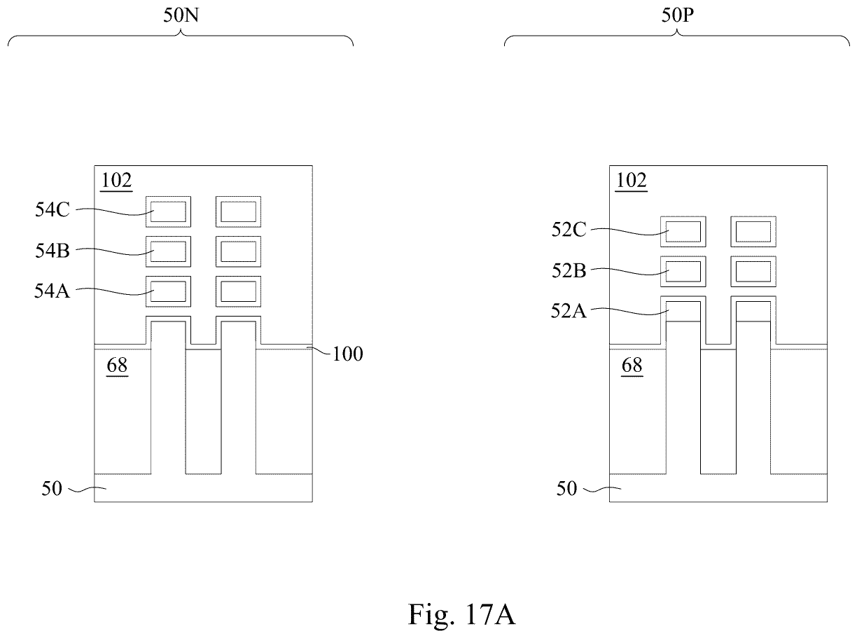

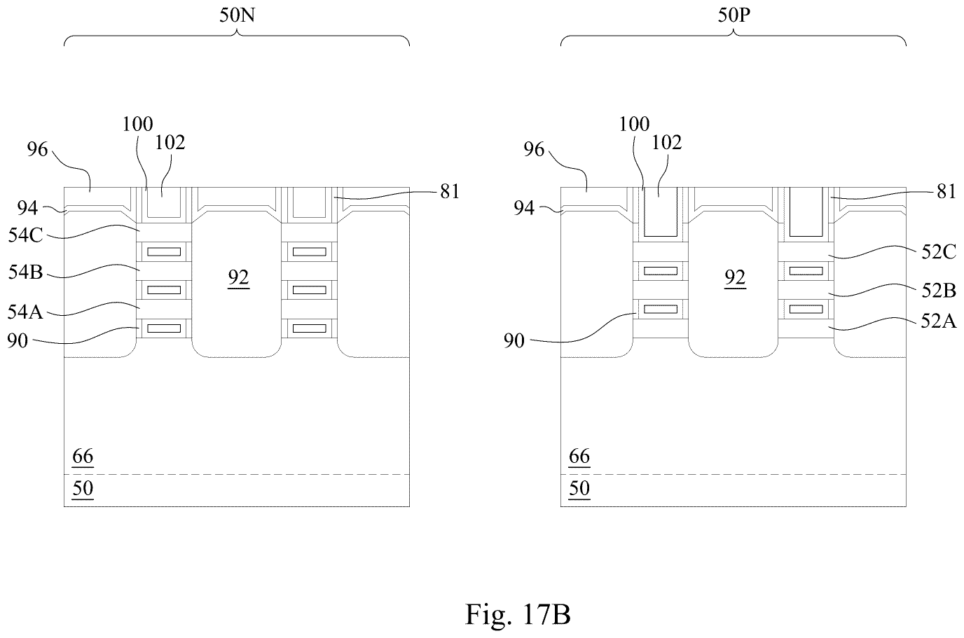

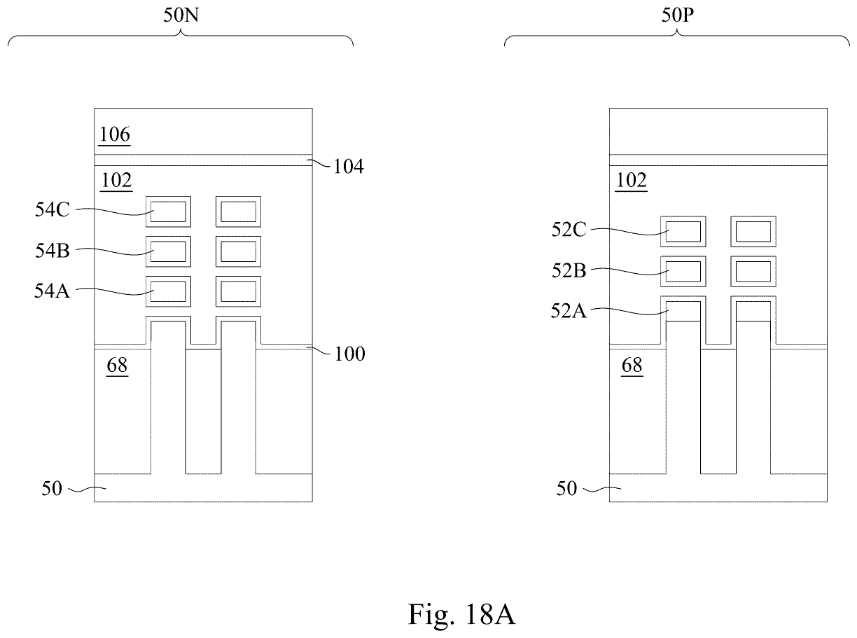

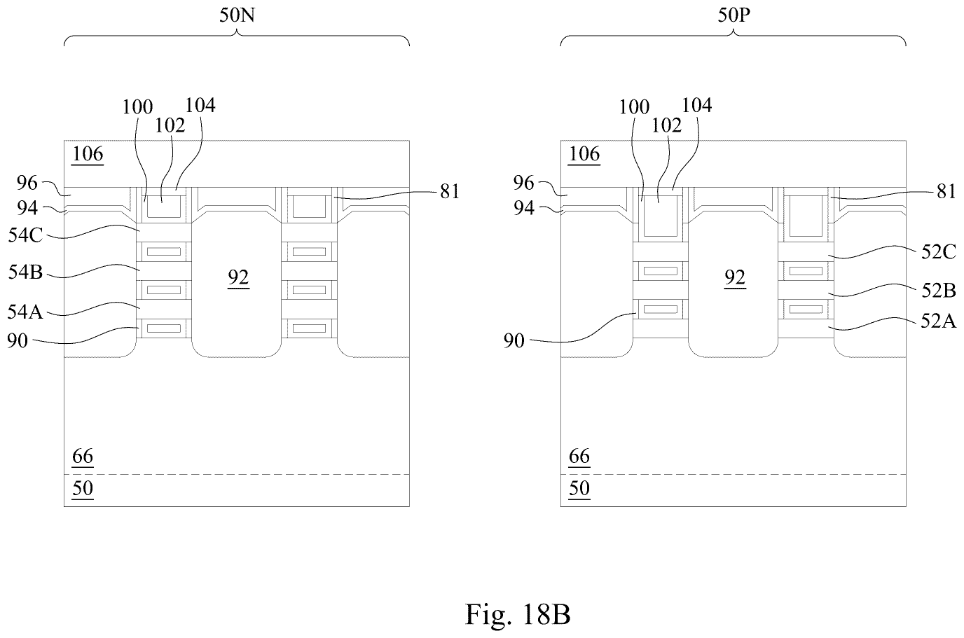

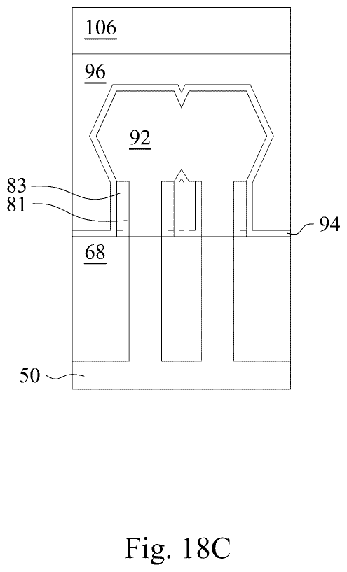

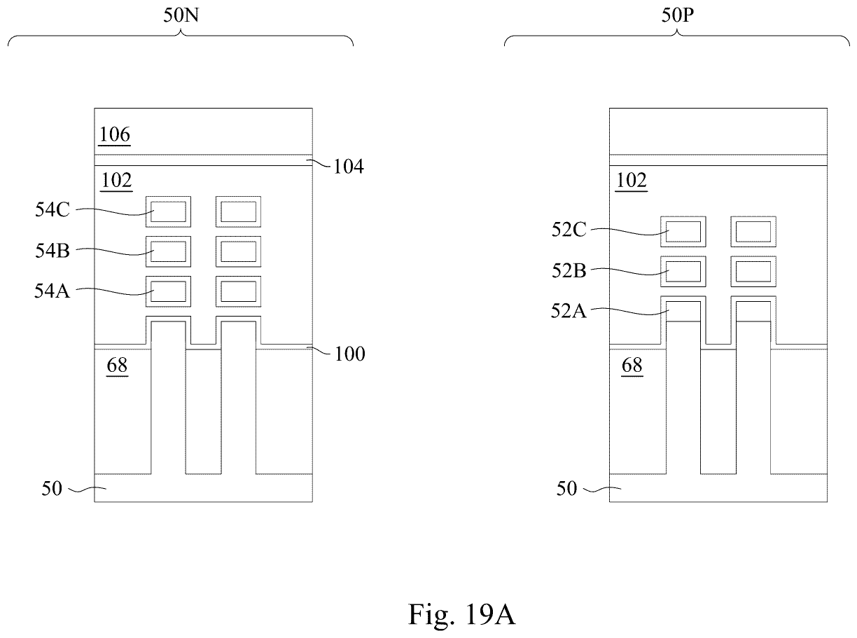

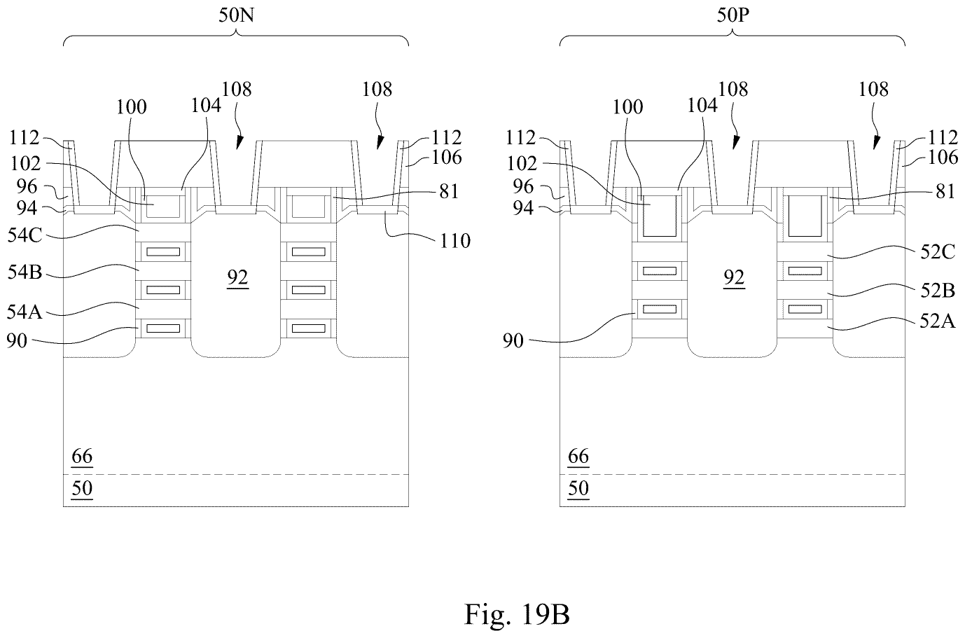

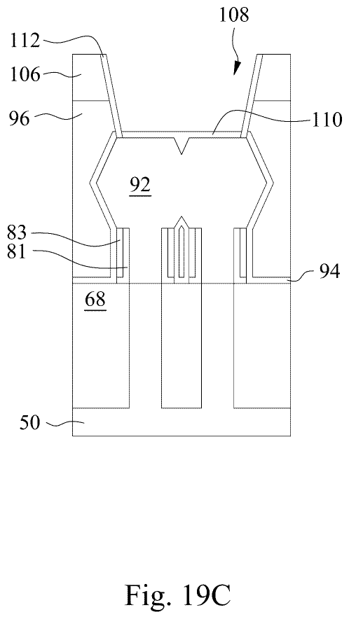

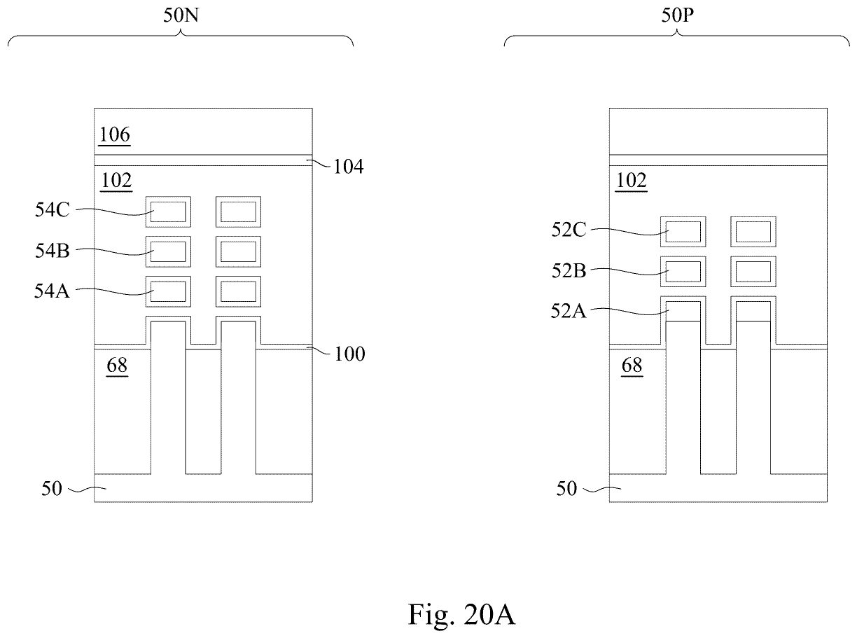

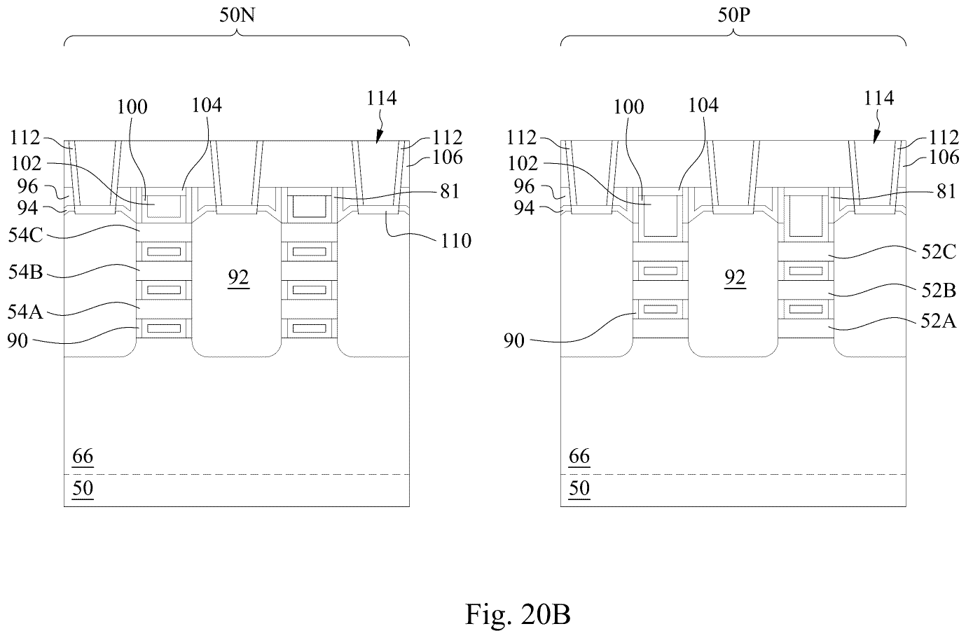

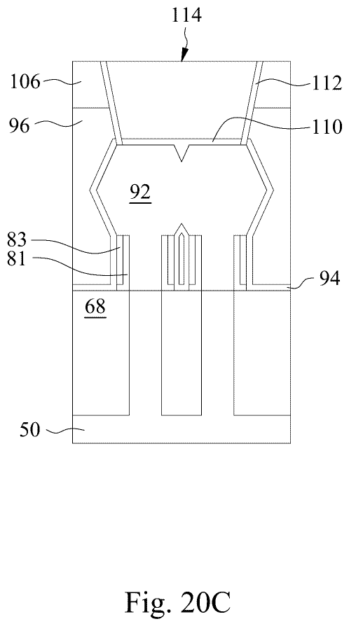

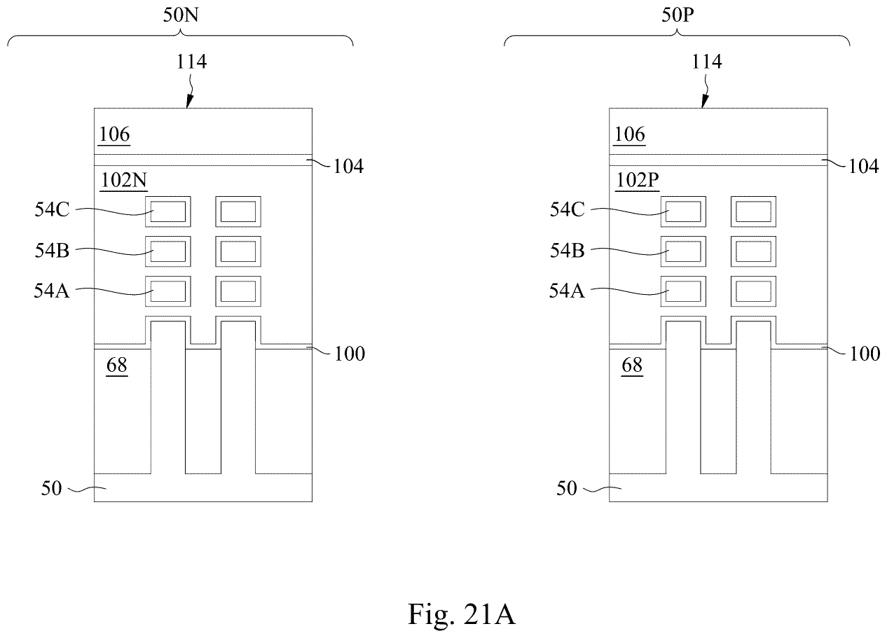

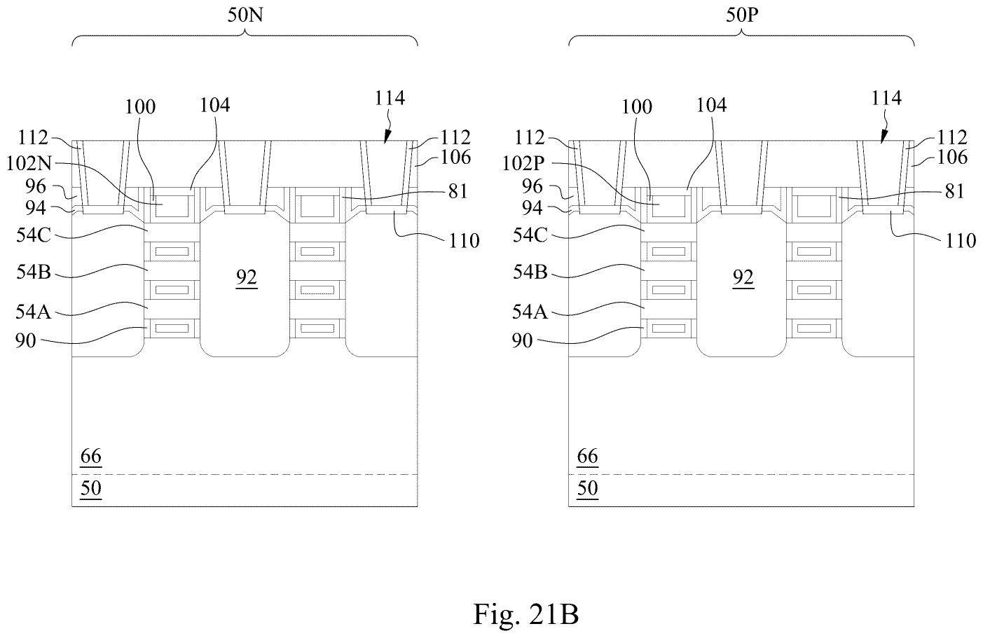

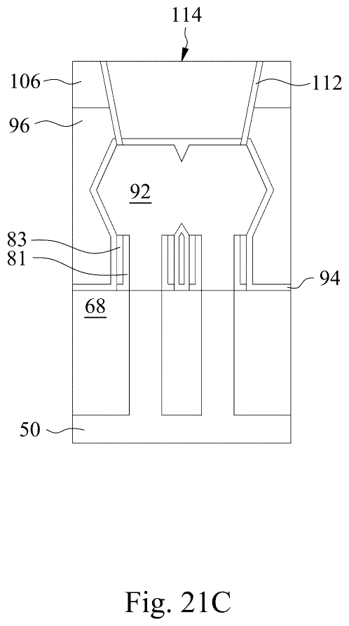

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously. FIGS. 21A, 21B, and 21C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

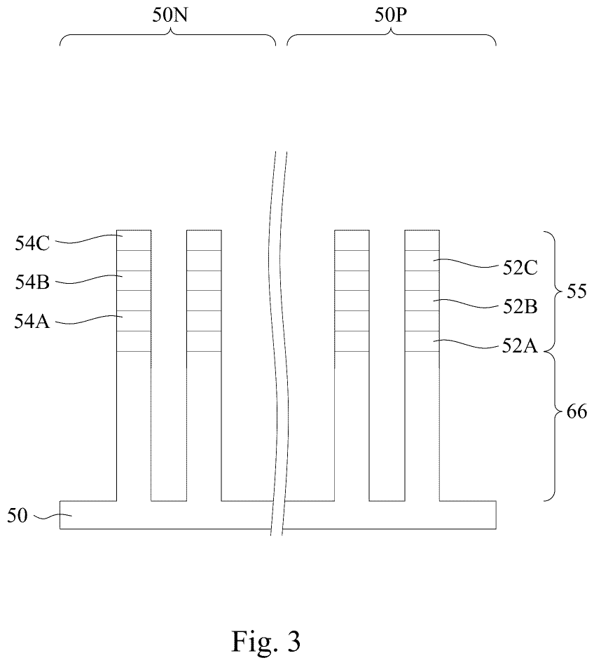

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

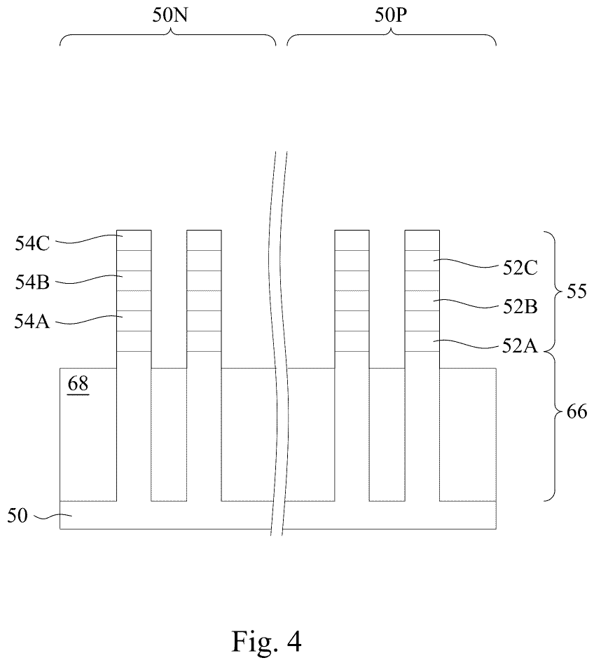

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

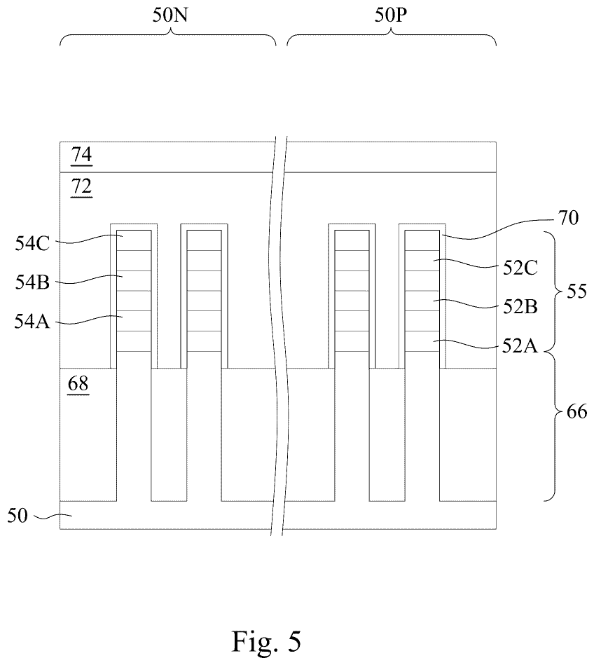

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions 68. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment devices. FIGS. 6A, 7A, 8A, 9A, 10A, 11A, 12A, 12C, 13A, 13C, 14A, 15A, and 18C illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 56 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

FIG. 10C illustrates other embodiments where portions of sidewalls of the layers of the multi-layer stack 64 formed of the first semiconductor materials (e.g., the first nanostructures 52) exposed by the first recesses 86 are etched to form sidewall recesses 88 in both the n-type region 50N and the p-type region 50P. In these embodiments, the channel regions in the n-type region 50N and the p-type region 50P may be formed simultaneously in subsequent processing, for example by removing the first nanostructures 52 in both the n-type region 50N and the p-type region 50P. In such embodiments, channel regions of n-type nano-FETs and p-type nano-FETS may have a same material composition, such as silicon, silicon germanium, or the like. FIGS. 21A, 21B, and 21C illustrate a structure resulting from such embodiments where the channel regions in both the p-type region 50P and the n-type region 50N are provided by the second nanostructures 54 and comprise silicon, for example.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12C) by subsequent etching processes, such as etching processes used to form gate structures.

In FIGS. 12A-12C, epitaxial source/drain regions 92 are formed in the first recesses 86. In some embodiments, the source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

In FIGS. 13A-13C, an interlayer dielectric (ILD) 96 is deposited over the structure illustrated in FIGS. 6A, 12B, and 12A (the processes of FIGS. 7A-12D do not alter the cross-section illustrated in FIGS. 6A), respectively. The ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying ILD 96.

In FIGS. 14A-14C, a planarization process, such as a CMP, may be performed to level the top surface of the ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the ILD 96 are level within process variations. Accordingly, the top surfaces of the dummy gates 76 are exposed through the ILD 96. In some embodiments, the masks 78 may remain, in which case the planarization process levels the top surface of the ILD 96 with top surface of the masks 78 and the first spacers 81.

In FIGS. 15A and 15B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 16A and 16B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 21A, 21B, and 21C illustrate a structure resulting from such embodiments where the channel regions in both the p-type region 50P and the n-type region 50N are provided by the second nanostructures 54 and comprise silicon, for example.

In FIGS. 17A and 17B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

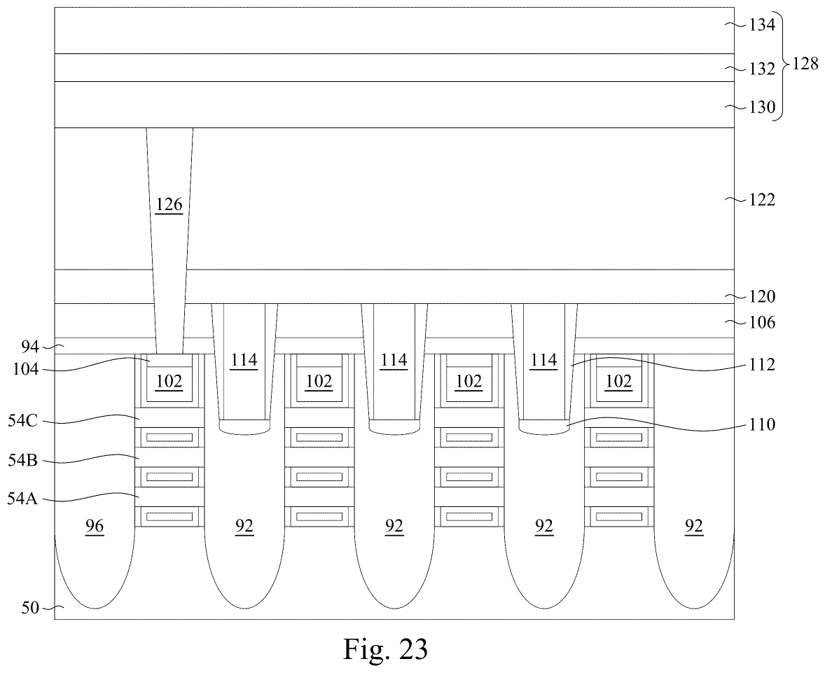

In FIGS. 18A-18C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the ILD 96. Subsequently formed gate contacts (such as the contacts 114, discussed below with respect to FIGS. 23A and 23B) penetrate through the gate mask 104 to contact the top surface of the recessed gate electrodes 102.

As further illustrated by FIGS. 18A-18C, an ILD 106 is deposited over the ILD 96 and over the gate mask 104. In some embodiments, the ILD 106 is a flowable film formed by FCVD. In some embodiments, the ILD 106 is formed of a dielectric material such as PSG, BSG, BPSG, USG, or the like, and may be deposited by any suitable method, such as CVD, PECVD, or the like.

In FIGS. 19A-19C, the ILD 106, the ILD 96, the CESL 94, and the gate masks 104 are etched to form third recesses 108 exposing surfaces of the epitaxial source/drain regions 92. The third recesses 108 may be formed by etching using an anisotropic etching process, such as RIE, NBE, or the like. In some embodiments, the third recesses 108 may be etched through the ILD 106 and the ILD 96 using a first etching process; may be etched through the gate masks 104 using a second etching process; and may then be etched through the CESL 94 using a third etching process. A mask, such as a photoresist, may be formed and patterned over the ILD 106 to mask portions of the ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 19B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

In some embodiments, contact spacers 112 are formed in the third recesses 108. The contact spacers may be formed before or after the silicide regions 110 but will be described as being formed after the silicide regions 110. The formation of contact spacers 112 within the third recesses 108 includes depositing a spacer material over the structure after the formation of the third recesses 108 and the silicide regions 110. In some embodiments, the spacer material is selected based on its etch selectivity relative to the surrounding materials, such as the ILD 106 and the silicide regions 110, to ensure that the spacer material can be selectively etched to form the contact spacers 112 without damaging adjacent structures. The spacer material may comprise silicon nitride, silicon oxide, silicon oxynitride, or other suitable dielectric materials. After deposition, an anisotropic etch process is employed to remove the spacer material from horizontal surfaces while retaining it on the sidewalls of the third recesses 108, thereby forming the contact spacers 112. These spacers 112 may serve to electrically isolate the contacts 114 from the gate structure 102 and other device features, as well as to protect the sidewalls of the third recesses 108 during subsequent metallization processes.

Next, in FIGS. 20A-C, contacts 114 (may also be referred to as contact plugs) are formed in the third recesses 108 between the contact spacers 112. The contacts 114 may each comprise one or more layers, such as barrier layers, diffusion layers, and fill materials. For example, in some embodiments, the contacts 114 each include a barrier layer and a conductive material, and is electrically coupled to the underlying conductive feature (e.g., silicide region 110 in the illustrated embodiment). The contacts 114 are electrically coupled to the silicide regions 110 and may be referred to as source/drain contacts 114. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the ILD 106.

FIGS. 21A-C illustrate cross-sectional views of a device according to some alternative embodiments. FIG. 21A illustrates reference cross-section A-A′ illustrated in FIG. 1. FIG. 21B illustrates reference cross-section B-B′ illustrated in FIG. 1. FIG. 21C illustrates reference cross-section C-C′ illustrated in FIG. 1. In FIGS. 21A-C, like reference numerals indicate like elements formed by like processes as the structure of FIGS. 20A-C. However, in FIGS. 21A-C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 21A-C may be formed, for example, by removing the first nanostructures 52 from both the p-type region 50P and the n-type region 50N simultaneously; depositing the gate dielectrics 100 and the gate electrodes 102P (e.g., gate electrode suitable for a p-type nano-FET) around the second nanostructures 54 in the p-type region 50P; and depositing the gate dielectrics 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

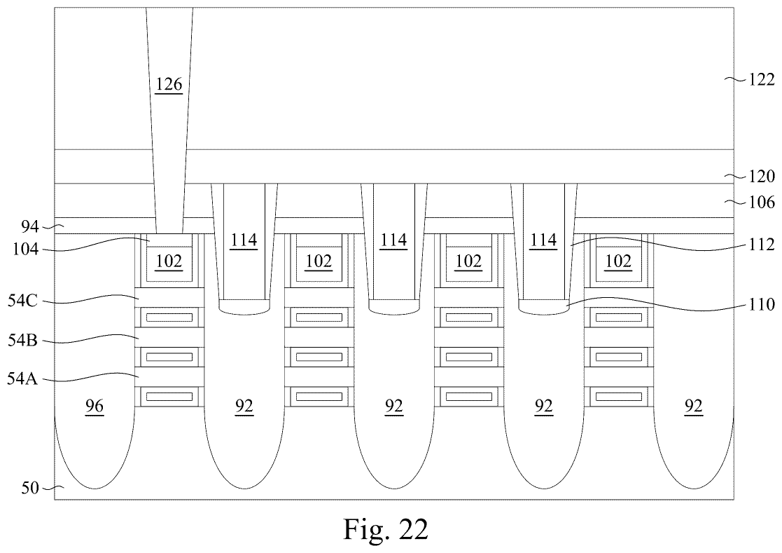

FIGS. 22 through 28C illustrate cross-sectional of further processing on the embodiment of FIGS. 20A-C in accordance with some embodiments. The further processing forms interconnect structures (sometimes referred to as front-side interconnect structures over the transistor structures. In some embodiments, the interconnect structures formed include gate contacts 126 and a via drain rail 148 (sometimes referred to as a power rail 148). These figures are illustrated using the embodiment illustrated in FIGS. 20A-C but are also applicable to the embodiment of FIGS. 21A-C. FIGS. 22 through 28C illustrate reference cross-section B-B′ illustrated in FIG. 1. These figures illustrate multiple source/drain regions 92 adjacent multiple gate structures 102 with source/drain contacts 114 coupled to each of the source/drain regions 114.

FIG. 22 illustrates the formation of CESL 120 (sometimes referred to as a middle CESL (MCESL) 120) and an ILD 122 over the previously formed structures, including the ILD 106 and the gate mask 104.

The MCESL 120 is formed over the ILD 106. In some embodiments, the MCESL 120 is formed of a carbon-containing low-k dielectric material, which is engineered to have a dielectric constant lower than silicon nitride, enhancing the device's performance by reducing parasitic capacitance. In these embodiments, the MCESL 120 is characterized by its density, which ranges from 1.9 to 2.0 g/cm³, and its composition, which includes silicon, carbon, nitrogen, and oxygen in the approximate percentages of 38/26/30/6 to 41/26/30/3. In some embodiments, the k-value of the MCESL 120 is about 4. In some embodiments, the MCESL 120 is formed using precursors such as ammonia (NH3) and tetramethylsilane, resulting in a film that provides both etch selectivity during patterning and electrical isolation for the device.

Subsequent to the formation of the MCESL 120, the ILD 122 is formed of a dielectric material such as PSG, BSG, BPSG, USG, or the like, and may be deposited by any suitable method, such as CVD, PECVD, or the like. The ILD 122 serves as an additional insulating layer, providing further electrical isolation between the various components of the semiconductor device.

Subsequent to the deposition of the ILD 122, a gate contact 126 is formed, extending through the ILD 122, the MCESL 120, the ILD 106, and the CESL 94. The gate contact 126 is electrically coupled to the gate electrode 102, providing a conductive pathway for electrical signals to and from the gate electrode 102. The formation of the gate contact 126 includes patterning and etching processes that are controlled to ensure accurate alignment and connectivity with the gate electrode 102.

The gate contact 126 may include a barrier layer (not shown). The barrier layer may include titanium, titanium nitride, tantalum, tantalum nitride, or the like. The conductive material of the gate contact 126 may be copper, a copper alloy, silver, gold, tungsten, cobalt, aluminum, nickel, the like, or a combination thereof. A planarization process, such as a CMP, may be performed to remove excess material from a surface of the ILD 122.

FIG. 23 illustrates the formation of a tri-layer photoresist 128 over the third interlayer dielectric (ILD) 122, which has been previously deposited over the ILD 106 and the gate mask 104. The tri-layer photoresist 128 comprises a bottom layer 130, a middle layer 132, and a photoresist layer 134. This tri-layer photoresist structure is designed to facilitate subsequent lithography and etching processes that define the via drain rail 148.

In some embodiments, the bottom layer 130 of the tri-layer photoresist serves a dual purpose. It can act as an adhesion promoter and as an anti-reflective coating. This can ensure adhesion of overlying layers and improve the fidelity of the photolithography process.

The middle layer 132 and the photoresist layer 134 of the tri-layer photoresist are patterned to create the desired features in the semiconductor device. The patterning process involves selectively removing portions of these layers, using a photolithography technique that transfers the desired pattern from a photomask to the photoresist layers. This patterned structure defines the areas where the via drain rail 148 will subsequently be formed.

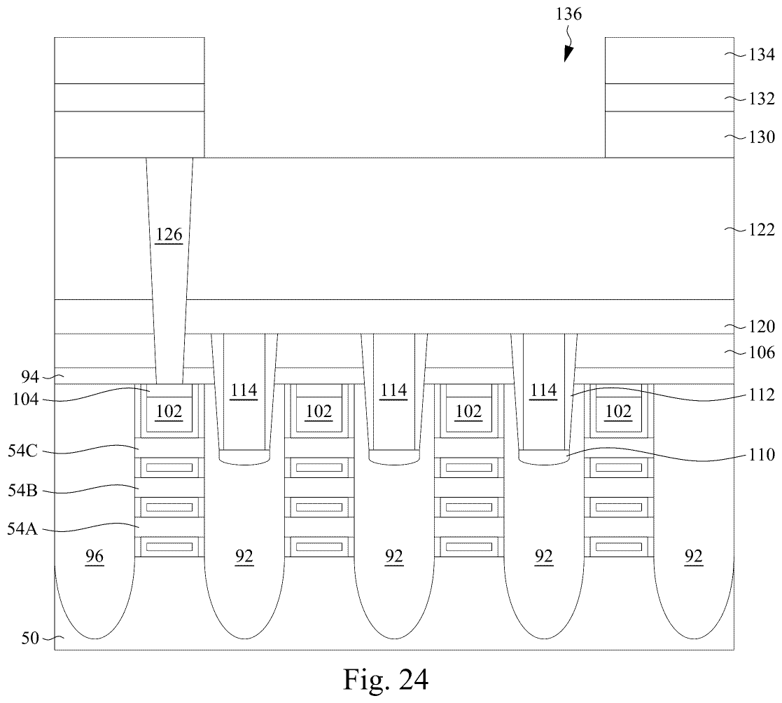

FIG. 24 illustrates the patterning of the layers of the tri-layer photoresist 128 to form a recess 136. The patterning process involves selectively removing portions of the photoresist layer 134, the middle layer 132, and the bottom layer 130, using a photolithography technique that transfers the desired pattern from a photomask to the photoresist layers. This patterned structure defines the areas where the via drain rail 148 will subsequently be formed. The recess 136 corresponds to the location and dimensions of the subsequently formed via drain rail 148.

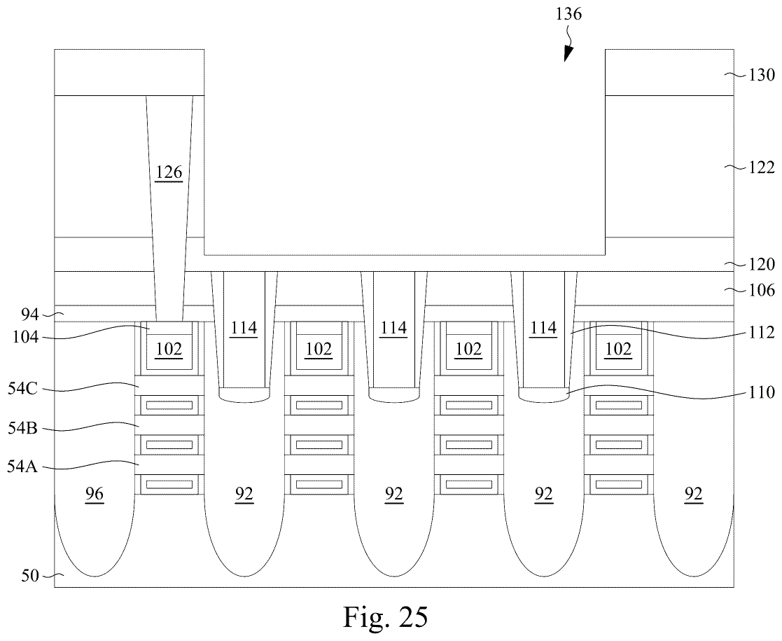

FIG. 25 illustrates the patterning of the ILD 122 using the tri-layer photoresist 128 as a mask to extend the recess 136. In some embodiments, the patterning is an etching process where the exposed areas of the ILD 122 are selectively removed. During this etching process, a gas mixture of C₄F₆/O₂/Ar is utilized under controlled conditions, with a pressure range of 20 to 60 milliTorr. In some embodiments, the etching is performed using a power setting of 100 to 900 Watts at a frequency of 2 MHz, combined with an additional power of 50 to 200 Watts at 27 MHz and 50 to 200 Watts at 60 MHz. These specific etching parameters are controlled to achieve the desired etch rate and selectivity. In some embodiments, as the etching progresses, the photoresist layer 134 and the middle layer 132 may be removed, leaving the bottom layer 130 intact. Depending on the etching conditions, the patterning step can extend partially into the MCESL 120 or can be stopped at the MCESL 120. The remaining bottom layer 130, after the patterning step, serves as an etch mask for subsequent etching processes that may further extend the recess 136 through the MCESL 120.

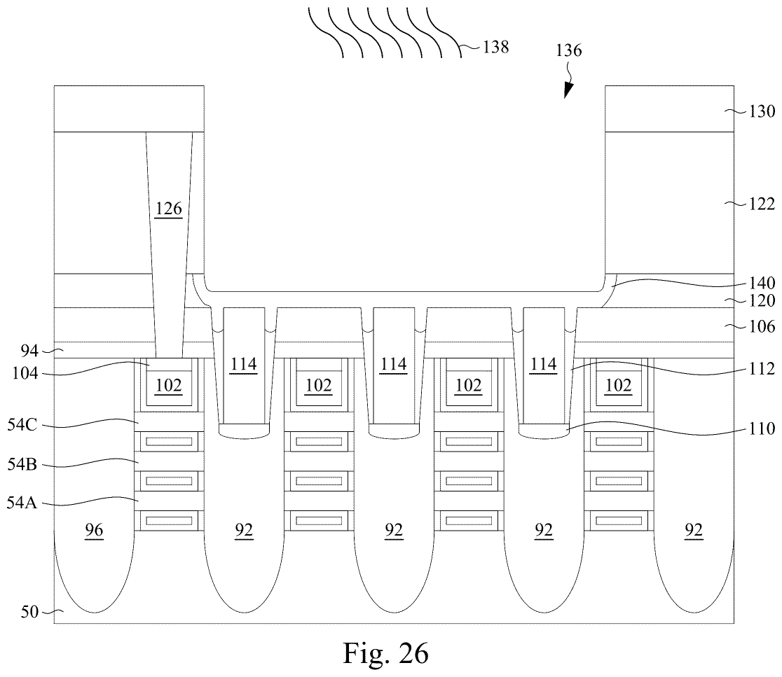

FIG. 26 illustrates performing a treatment process 138 to the structure, resulting in the formation of a treatment layer 140 within the recess 136. The treatment process 138 modifies portions of the contact spacers 112 and the MCESL 120 to form the treatment layer 140. This treatment layer 140 is designed to enhance the protective properties of the contact spacers 112 and the MCESL 120, improving the device's resistance to leakage and other forms of electrical interference.

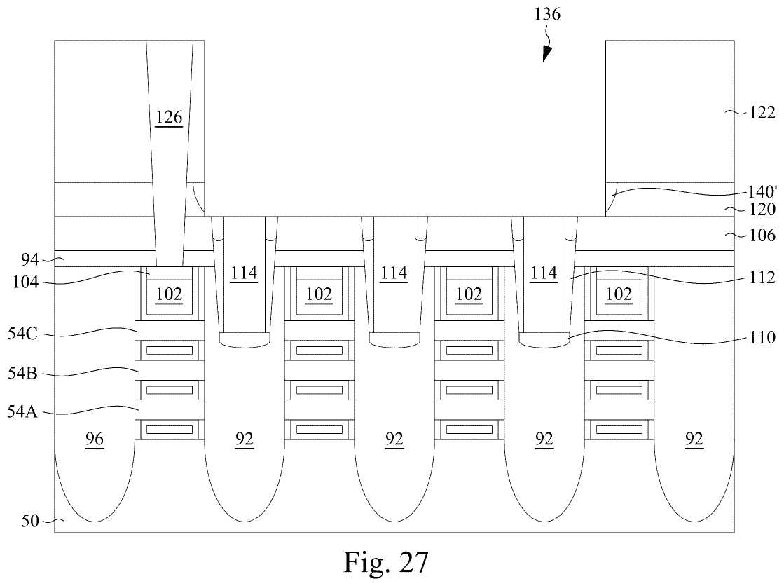

In some embodiments, the treatment process 138 comprises an oxygen-based treatment that converts the exposed portions of the low-k MCESL 120 and the silicon nitride contact spacers 112 into an oxide or an oxide-like material. This transformation results in the formation of oxide plugs 140′ (see, e.g., FIG. 27) that are adjacent to the via drain rail 148 in the low-k MCESL 120 and adjacent to the source/drain contacts 114 in the contact spacers 112. The oxide plugs 140′ serve to electrically isolate the subsequently formed via drain rail 148 from the surrounding structures and prevent potential short-circuiting or leakage paths that could compromise the performance of the semiconductor device. Further, the treatment layer 140 has a lower etch rate to the subsequent etching process that extend through the MCESL 120 to the contacts 114 than the unmodified MCESL 120 and the unmodified contact spacers 112. Thus, the treatment layer 140 prevents the MCESL 120 and contact spacers 112 from being over etched during that process and forming recesses or protrusions for subsequent conductive features to fill.

In some embodiments, the oxygen-based treatment may involve exposing the recess 136 to an oxygen-containing gas at a pressure ranging from 10 to 100 milliTorr and at a power in a range from 50 to 600 Watt at a frequency 60 MHz. The oxygen-containing gas may consist of pure oxygen or may further comprise an inert gas selected from the group consisting of nitrogen, argon, and noble gases.

FIG. 27 illustrates a further etching process that extends the recess 136 through the MCESL 120 to expose the top surfaces of the contacts 114. During this etching process, a gas mixture of CH₃F/H₂ is utilized under conditions of 10 to 50 milliTorr pressure, with a dual-frequency power application of 20 to 100 Watts at 2 MHz and 200 to 900 Watts at 60 MHz. These specific etching parameters are controlled to selectively remove portions of the previously formed treatment layer 140, leaving behind the remaining portions which form oxide plugs 140′. The material composition of these oxide plugs 140′ has been modified by the treatment process 138 to exhibit different properties compared to the original material of the MCESL 120 and the contact spacers 112. For example, the oxide plugs 140′ may have a higher oxygen content, which enhances their electrical isolation properties. Located adjacent to the first conductive feature within the low-k MCESL 120 and adjacent to the source/drain contacts 114 within the contact spacers 112, the oxide plugs 140′ serve to electrically isolate the via drain rail 148, which will be formed in the recess 136, from the surrounding device features. This isolation enhances the reliability and performance of the semiconductor device by preventing electrical shorts and leakage paths.

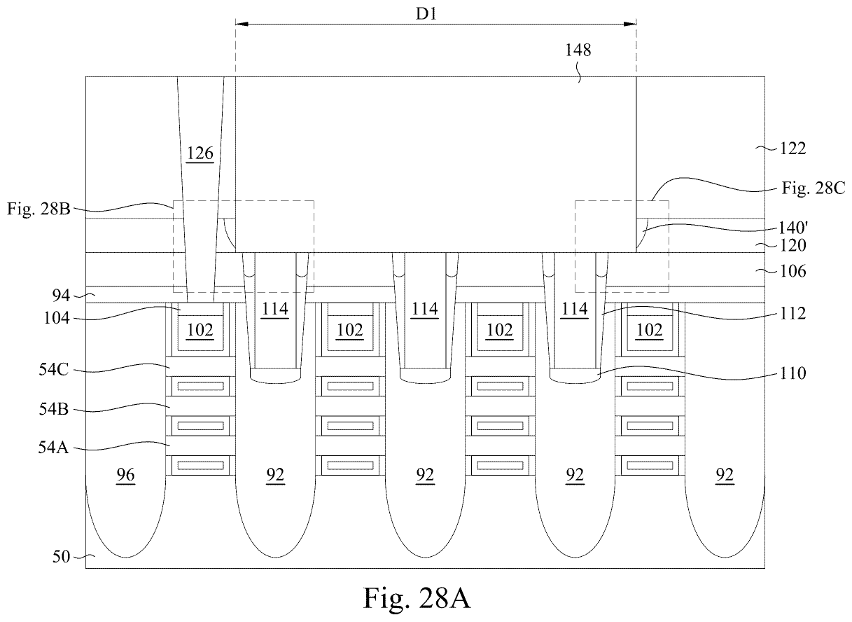

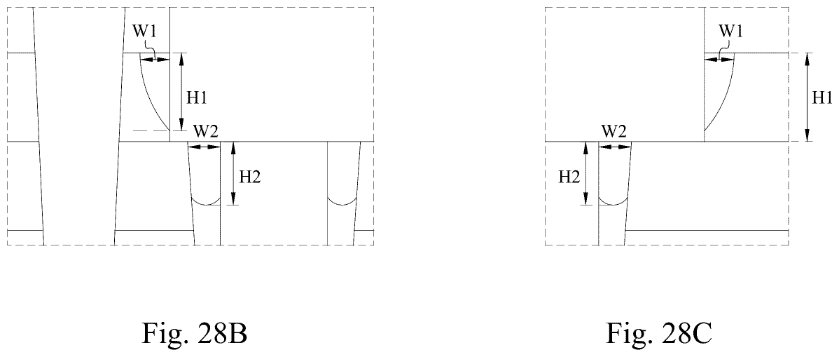

FIG. 28A illustrates the formation of the via drain rail 148 within the recess 136. The via drain rail 148 is formed to span a specific distance D1 across the semiconductor device structure, providing a conductive pathway that connects multiple source/drain contacts 114. The distance D1 between the outer sidewalls of the via drain rail 148 in this cross-sectional view may range from about 20 nm to about 1000 nm, depending on the design requirements of the semiconductor device. The via drain rail 148 is a component in the distribution of power within the device, particularly in structures such as ring oscillators or other integrated circuits requiring a uniform power distribution across multiple transistors.

FIG. 28A illustrates the formation of the via drain rail 148 within the recess 136. The via drain rail 148 may comprise of a metal such as copper or tungsten. The via drain rail 148 is formed to span a distance D1 across the semiconductor device structure, providing a conductive pathway that connects multiple source/drain contacts 114. In some embodiments, the distance D1 between the outer sidewalls of the via drain rail 148 in this cross-sectional view may range from about 20 nm to about 1000 nm, depending on the design requirements of the semiconductor device.

The metal is deposited into the recess 136, filling it to form the via drain rail 148. Following the deposition, a planarization process, such as chemical mechanical polishing (CMP), may be performed to level the top surface of the via drain rail 148 with the surrounding ILD 122. This ensures a uniform surface topology for subsequent fabrication steps. The via drain rail 148 serves as a component in the distribution of power within the device, for example, in structures such as ring oscillators or other integrated circuits that require a uniform power distribution across multiple transistors.

As discussed above, the treatment layer 140 has a lower etch rate to the etching process illustrated in FIG. 27 such that the treatment layer 140 prevented the MCESL 120 and contact spacers 112 from being over etched during that process. If these layers are allowed to over etch, recesses or protrusions would have formed and would be filled with the conductive material of the via drain rail 148. These protrusions of conductive material of the via drain rail 148 can cause leakage issues for the device.

FIGS. 28B and 28C provide magnified views of portions of FIG. 28A, highlighting the protective features formed around the via drain rail 148. The remaining treatment layer 140′ (also referred to as oxide plugs 140′), which results from the oxygen-based treatment process 138, is shown to surround the lower portion of the via drain rail 148, forming a protective barrier. The width W1 and height H1 of the treatment layer 140′ are depicted, indicating the dimensions of the remaining treatment layer 140′ in the MCESL 120 that prevents leakage between the via drain rail 148 and adjacent structures. In some embodiments, the width W1 of the remaining treatment layer 140′ is in a range from 1 nm to 5 nm and the height H1 is in a range from 2 nm to 9 nm. The width W2 and height H2 of the treatment layer 140′ are depicted, indicating the dimensions of the remaining treatment layer 140′ in the contact spacers 112 that prevents leakage between the via drain rail 148 and adjacent structures. In some embodiments, the width W2 of the remaining treatment layer 140′ is in a range from 1 nm to 3 nm and the height H1 is in a range from 1 nm to 5 nm. These dimensions are controlled to ensure that the oxide plugs 140′ provide adequate protection without adversely affecting the structural integrity or electrical properties of the semiconductor device.

The heights H1 and H2 of the remaining treated layer 140′ is correlated to the power used in the oxygen-based treatment 138, such that higher power treatments may have larger heights of remaining treated layer 140′. Conversely, lower power treatments may have smaller heights of remaining treated layer 140′. In addition, the widths W1 and W2 of the remaining treated layer 140′ is correlated to the pressure used in the oxygen-based treatment 138, such that higher pressure treatments may have larger widths of remaining treated layer 140′. Conversely, lower pressure treatments may have smaller widths of remaining treated layer 140′.

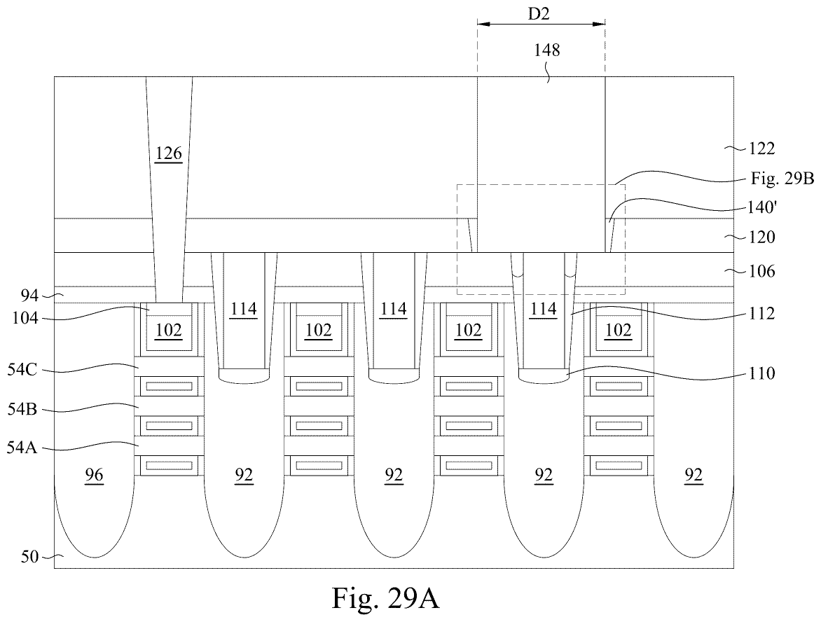

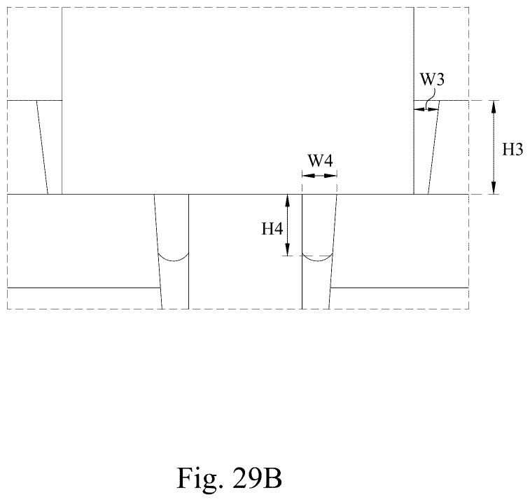

FIGS. 29A and 29B illustrate cross-sectional views of further processing of the nano-FETS, in accordance with some embodiments. FIG. 29A illustrates a semiconductor device structure where the via drain rail 148 is formed to connect to a single contact 114, as opposed to multiple contacts 114 in previous embodiments. The via drain rail 148 spans a distance D2 across the semiconductor device structure, which may range from about 20 nm to about 1000 nm, depending on the design requirements of the semiconductor device. In some embodiments, the distance D2 is smaller than the distance D1. This embodiment demonstrates the adaptability of the via drain rail 148 size and its impact on the overall device structure and performance. The embodiments of FIGS. 28A-C and 29A-B can be formed on the same integrate circuit device.

In some embodiments, when the via drain rail 148 is larger, the widths and heights of the treatment layer 140′ are larger to further ensure isolation of the via drain rail 148. In addition, a ratio of D1/D2 is about 10, a ratio of W1/W3 is in a range from 1 to 4, a ratio of H1/H3 is in a range from 1 to 9, a ratio of W2/W4 is in a range from 1 to 3, and a ratio of H2/H4 is in a range from 1 to 5.

FIG. 29B provides a magnified view of the protective features formed around the via drain rail 148 within the semiconductor device structure. The width W3 and height H3 represent the dimensions of the remaining treatment layer 140′ in the MCESL 120, while the width W4 and height H4 represent the dimensions of the remaining treatment layer 140′ in the contact spacers 112. These dimensions are indicative of the protective barrier formed by the oxygen-based treatment process 138, which is designed to prevent leakage between the via drain rail 148 and adjacent structures, enhancing the reliability and performance of the semiconductor device. The specific dimensions of W3, H3, W4, and H4 are controlled to provide adequate protection without compromising the structural integrity or electrical properties of the device.

Embodiments may achieve advantages. The disclosed embodiments include a semiconductor device structure that incorporates a carbon-containing low-k dielectric material as a middle contact etch stop layer (MCESL). This approach offers several advantages and benefits over traditional methods. The use of a carbon-containing low-k material in the MCESL results in a lower dielectric constant, which effectively reduces parasitic capacitance within the device. This reduction in capacitance can lead to improved RC delay effects, enhancing the overall speed and performance of the semiconductor device.

The disclosed embodiments further include the application of an oxygen-based treatment during the via drain rail (VDR) etching process. This treatment modifies the sidewalls of the low-k MCESL and the contact spacers, forming an oxide-like protective layer. The formation of this protective layer serves as a barrier against leakage currents, particularly between the VDR and the metal gate regions. This protection helps to maintain the integrity and reliability of the device, especially as feature sizes continue to decrease in advanced semiconductor manufacturing.

The oxygen-based treatment also contributes to the improvement of the overlay window between the via and the gate by preventing protrusions of the VDR. This results in a more uniform and precise VDR profile, which is beneficial for the alignment and connectivity of various device components. Additionally, the treatment conditions, such as power and pressure, can be adjusted to tailor the width and thickness of the protective layer, providing flexibility in the design and fabrication process.

In an embodiment, a method may include forming a first interlayer dielectric (ILD) over a transistor structure. The method may also include forming first conductive contacts through the first ILD to the transistor structure. Furthermore, the method may include forming a first contact etch stop layer (CESL) over the first conductive contacts and the first ILD. In addition, the method may include forming a second ILD over the first CESL. Moreover, the method may include forming a second conductive contact through the second ILD, the first CESL, and first ILD to the transistor structure. The method may also include etching a recess into the second ILD and the first CESL. Furthermore, the method may include performing a treatment in the recess to form a treated layer in the first CESL. Additionally, the method may include forming a first conductive feature in the recess, the first conductive feature being electrically coupled to the first conductive contacts.

The described embodiments may also include one or more of the following features. The method may include where the first CESL may include a carbon-containing material. The method may include where the first CESL has a k value lower than silicon nitride. Additionally, the method may include forming contact spacers on sidewalls of the first conductive contacts prior to the forming the first CESL. The method may also include performing the treatment in the recess forms the treated layer in the contact spacers. Moreover, the contact spacers may include silicon nitride. At least one of the contact spacers may extend from the transistor structure through the first ILD to the first CESL. The treatment may include exposing the recess to pure oxygen. The treatment may also include exposing the recess to one or more gases selected from the group having of nitrogen, argon, and noble gases.

In an embodiment, a method may include forming a transistor structure, the transistor structure having source and drain regions adjacent to a gate electrode. The method may also include depositing a first interlayer dielectric (ILD) layer over the gate electrode and the source and drain regions. Furthermore, the method may include patterning the first ILD layer to expose portions of the source and drain regions. In addition, the method may include forming source/drain contacts through the first ILD layer and electrically coupled to the source and drain regions. Moreover, the method may include forming contact spacers on sidewalls of the source/drain contacts. The method may also include forming a low-k contact etch stop layer (CESL) over the first ILD layer, the source/drain contacts, and the contact spacers. Furthermore, the method may include depositing a second ILD layer over the low-k CESL, patterning the second ILD layer and the low-k CESL to form a first recess. Additionally, the method may include applying a treatment in the first recess to modify the low-k CESL and the contact spacers. Moreover, the method may include forming a first conductive feature in the first recess, the first conductive feature being electrically coupled to the source/drain contacts.

The described embodiments may also include one or more of the following features. The method may include forming a gate contact through the second ILD, the low-k CESL, and the first ILD, the gate contact being electrically coupled to the gate electrode of the transistor structure. The contact spacers may include a material selected from the group having of silicon nitride, silicon oxynitride, and combinations thereof, and the low-k CESL may include a material having a lower k-value than the material of the contact spacers. The low-k CESL may include silicon, carbon, nitrogen, and oxygen. The treatment may include an oxygen-based treatment performed in-situ with the patterning the second ILD layer and the low-k CESL to form the first recess. The treatment may also include an oxygen-based treatment ex-situ with the patterning the second ILD layer and the low-k CESL to form the first recess. The contact spacers are formed before the source/drain contacts. The treatment may include exposing the first recess to an oxygen-containing gas where the oxygen-containing gas further may include one or more gases selected from the group having of nitrogen, argon, and noble gases.

In an embodiment, a semiconductor device may include a transistor structure having source and drain regions adjacent to a gate electrode. The semiconductor device may also include a first interlayer dielectric (ILD) layer over the gate electrode and the source and drain regions. Furthermore, the device may include source/drain contacts extending through the first ILD layer and electrically coupled to the source and drain regions. In addition, the device may include contact spacers on sidewalls of the source/drain contacts. Moreover, the device may include a low-k contact etch stop layer (CESL) over the first ILD layer, the source/drain contacts, and the contact spacers. The device may also include a second ILD layer over the low-k CESL. Furthermore, the device may include a first conductive feature in the second ILD and the low-k CESL, the first conductive feature being electrically coupled to the source/drain contacts. Additionally, the device may include insulating plugs in the low-k CESL and the contact spacers, the insulating plugs being adjacent the first conductive feature in the low-k CESL and adjacent the source/drain contacts in the contact spacers.

The described embodiments may also include one or more of the following features. The contact spacers may include a material selected from the group having of silicon nitride, silicon oxynitride, and combinations thereof, and the low-k CESL may include a material having a lower k-value than the material of the contact spacers. The first conductive feature may include a material selected from the group having of copper, tungsten, aluminum, and combinations thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first interlayer dielectric (ILD) over a transistor structure;
forming first conductive contacts through the first ILD to the transistor structure;
forming a first contact etch stop layer (CESL) over the first conductive contacts and the first ILD;
forming a second ILD over the first CESL;
forming a second conductive contact through the second ILD, the first CESL, and first ILD to the transistor structure;
etching a recess into second ILD and the first CESL;
performing a treatment in the recess to form a treated layer in the first CESL; and
forming a first conductive feature in the recess, the first conductive feature being electrically coupled to the first conductive contacts.

2. The method of claim 1, wherein the first CESL comprises a carbon-containing material.

3. The method of claim 1, wherein the first CESL has a k value lower than silicon nitride.

4. The method of claim 1, further comprising:
forming contact spacers on sidewalls of the first conductive contacts prior to the forming the first CESL.

5. The method of claim 4, wherein performing the treatment in the recess forms the treated layer in the contact spacers.

6. The method of claim 4, wherein the contact spacers comprise silicon nitride.

7. The method of claim 4, wherein at least one of the contact spacers extends from the transistor structure through the first ILD to the first CESL.

8. The method of claim 1, wherein the treatment comprises exposing the recess to pure oxygen.

9. The method of claim 1, wherein the treatment comprises exposing the recess to one or more gases selected from the group consisting of nitrogen, argon, and noble gases.

10. A method, comprising:
forming a transistor structure, the transistor structure comprising source and drain regions adjacent to a gate electrode;
depositing a first interlayer dielectric (ILD) layer over the gate electrode and the source and drain regions;
patterning the first ILD layer to expose portions of the source and drain regions;
forming source/drain contacts through the first ILD layer and electrically coupled to the source and drain regions;
forming contact spacers on sidewalls of the source/drain contacts;
forming a low-k contact etch stop layer (CESL) over the first ILD layer, the source/drain contacts, and the contact spacers;
depositing a second ILD layer over the low-k CESL;
patterning the second ILD layer and the low-k CESL to form a first recess;
applying an treatment in the first recess to modify the low-k CESL and the contact spacers; and
forming a first conductive feature in the first recess, the first conductive feature being electrically coupled to the source/drain contacts.

11. The method of claim 10, further comprising:
forming a gate contact through the second ILD, the low-k CESL, and the first ILD, the gate contact being electrically coupled to the gate electrode of the transistor structure.

12. The method of claim 10, wherein the contact spacers comprise a material selected from the group consisting of silicon nitride, silicon oxynitride, and combinations thereof, and wherein the low-k CESL comprises a material having a lower k-value than the material of the contact spacers.

13. The method of claim 12, wherein the low-k CESL comprises silicon, carbon, nitrogen, and oxygen.

14. The method of claim 10, wherein the treatment comprises an oxygen-based treatment performed in-situ with the patterning the second ILD layer and the low-k CESL to form the first recess.

15. The method of claim 10, wherein the treatment comprises an oxygen-based treatment ex-situ with the patterning the second ILD layer and the low-k CESL to form the first recess.

16. The method of claim 10, wherein the contact spacers are formed before the source/drain contacts.

17. The method of claim 10, wherein the treatment comprises exposing the first recess to an oxygen-containing gas, wherein the oxygen-containing gas further comprises one or more gases selected from the group consisting of nitrogen, argon, and noble gases.

18. A semiconductor device, comprising:
a transistor structure comprising source and drain regions adjacent to a gate electrode;
a first interlayer dielectric (ILD) layer over the gate electrode and the source and drain regions;
source/drain contacts extending through the first ILD layer and electrically coupled to the source and drain regions;
contact spacers on sidewalls of the source/drain contacts;
a low-k contact etch stop layer (CESL) over the first ILD layer, the source/drain contacts, and the contact spacers;
a second ILD layer over the low-k CESL;
a first conductive feature in the second ILD and the low-k CESL, the first conductive feature being electrically coupled to the source/drain contacts; and
insulating plugs in the low-k CESL and the contact spacers, the insulating plugs being adjacent the first conductive feature in the low-k CESL and adjacent the source/drain contacts in the contact spacers.

19. The semiconductor device of claim 18, wherein the contact spacers comprise a material selected from the group consisting of silicon nitride, silicon oxynitride, and combinations thereof, and wherein the low-k CESL comprises a material having a lower k-value than the material of the contact spacers.

20. The semiconductor device of claim 18, wherein the first conductive feature comprises a material selected from the group consisting of copper, tungsten, aluminum, and combinations thereof.
